(19) United States
(12) Patent Application Publication
(10) Pub. No.: US 2014/0078154 A1
(43) Pub. Date: Mar. 20, 2014

(54) DISPLAY APPARATUS WITH MULTI-HEIGHT SPACERS

(71) Applicants: Richard S. Payne, Andover, MA (US); Timothy J. Brosnihan, Natick, MA (US); Eugene E. Fike, III, Amesbury, MA (US)

(72) Inventors: Richard S. Payne, Andover, MA (US); Timothy J. Brosnihan, Natick, MA (US); Eugene E. Fike, III, Amesbury, MA (US)

(73) Assignee: Pixtronix, Inc., San Diego, CA (US)

(21) Appl. No.: 13/618,291

(22) Filed: Sep. 14, 2012

(51) Int. Cl. G02B 26/02; G06F 15/00; G03F 7/20; B32B 3/30; B05D 5/12; B05D 3/10; G02B 26/00; B32B 3/10

(52) U.S. Cl. 345/501; 359/290; 359/230; 428/201; 428/166; 427/58; 216/11; 430/320

(57) ABSTRACT

A device includes an array of devices formed on a first substrate. A second substrate is spaced away from the first substrate such that the array of devices are positioned between the first and second substrates. A plurality of spacers are coupled to the first substrate to maintain at least a minimum gap between the first substrate and the second substrate. The plurality of spacers include a first set of spacers and a second set of spacers. The spacers in the first set of spacers are shorter than the spacers in the second set of spacers. In some implementations, the device is a display device and the MEMS devices are modulators.

### TECHNICAL FIELD

This disclosure relates to the field of displays, and in particular, to fabrication and uses of microelectromechanical systems (MEMS) spacer structures.

### DESCRIPTION OF THE RELATED TECHNOLOGY

Electromechanical systems (EMS) devices, such as nanoelectromechancial systems (NEMS) and microelectromechanical systems (MEMS) devices, can include hundreds, thousands, or in some cases, millions of moving elements. Some EMS devices are constructed to operate between two substrates. Spacers can be used to maintain a minimum gap between such substrates, while still allowing one substrate to have some flexibility. In EMS-based display devices, deformation of this substrate, however, can lead to optical defects.

### SUMMARY

The systems, methods and devices of the disclosure each have several innovative aspects, no single one of which is solely responsible for the desirable attributes disclosed herein.

One innovative aspect of the subject matter described in this disclosure can be implemented in an apparatus having an array of devices formed on a first substrate. The apparatus also includes a second substrate spaced away from the first substrate such that the array of devices are positioned between the first and second substrates. A plurality of spacers is coupled to the first substrate to maintain at least a minimum gap between the first substrate and the second substrate. The plurality of spacers include a first set of spacers and a second set of spacers. The spacers in the first set of spacers are shorter than the spacers in the second set of spacers. At least one spacer in the second set of spacers is positioned between at least two spacers in the first set of spacers. In some implementations, the spacers in the first set of spacers are sufficiently tall to prevent the devices from coming into contact with the second substrate. In some implementations, a liquid fills a gap between the first and second substrates.

In some implementations, groups of spacers from the first and second sets of spacers can be co-located to form a plurality of regions of spacers having lower-spacers and a plurality of regions of spacers having higher spacers. In some of these implementations, a first group of spacers, including spacers from the second set of spacers, is positioned about the perimeter of the first substrate, and a second group of spacers, including spacers from the first set of spacers, is positioned within an interior region of the first substrate. A third group of spacers, including spacers from the second set of spacers, is positioned within the interior region of the first substrate such that at least one spacer in the second group of spacers is located between at least one spacer in the first group of spacers and at least one spacer in the third group of spacers.

In some other implementations, a first group of spacers, including spacers from the second set of spacers, is positioned about the perimeter of the device, and a second group of spacers, including spacers from the first set of spacers, is positioned within an interior region of the first substrate. A plurality of third groups of spacers, including spacers from the second set of spacers, are positioned within the interior region of the first substrate such that at least one spacer in the second group of spacers is located between at least one spacer in the first group of spacers and at least one spacer in each respective third group of spacers.

In some implementations, the devices in the array include display elements and the apparatus includes a display incorporating the display elements. In some implementations, the display elements are light modulators. In some implementations, the display elements include electromechanical systems (EMS) light modulators. In some such implementations, the EMS light modulators include microelectromechanical systems (MEMS) shutter assemblies.

In some implementations, the apparatus also includes a processor that is configured to communicate with the display and a memory device that is configured to communicate with the processor. The processor is configured to process image data. In some implementations, the apparatus also includes a driver circuit configured to send at least one signal to the display and a controller configured to send at least a portion of the image data to the driver circuit. In some implementations, the apparatus further includes an image source module configured to send the image data to the processor. The image source module can include at least one of a receiver, transceiver, and transmitter. In some other implementations, the apparatus includes an input device configured to receive input data and to communicate the input data to the processor.

In some other implementations, the devices comprise EMS devices other than display elements.

The spacers can be formed from a metal encapsulating polymer projections extending away from the first substrate. In some implementations, the spacers are encapsulated by a conductive material. In some implementations, the electrically conductive spacers electrically connect at least a portion of the each of the devices to a conductive element formed on the second substrate.

In some implementations, the first set of spacers can include two polymer layers and the second set of spacers can include three polymer layers. In some other implementations, the first set of spacers includes a first polymer layer having a first height and a second polymer layer having a second height, and the second set of spacers includes a first polymer layer having the first height and a second polymer layer having a third height greater than the second height.

Another innovative aspect of the subject matter described in this disclosure can be implemented in a method of forming a plurality of spacers. The method includes forming an array of devices on a substrate, forming a first set of spacers on the substrate, and forming a second set of spacers on the substrate. Each of the spacers in the first set of spacers has a first height, and each of the spacers in the second set of spacers has a second height, which is taller than the first height. At least one spacer in the second set of spacers is formed between at least two spacers in the first set of spacers.

In some implementations, forming the first and second sets of spacers includes patterning a layer of polymer material with a grayscale mask such that a smaller portion of the polymer material remains to form a portion of the first set of spacers than remains for the second set of spacers. In some other implementations, forming the first and second sets of spacers includes depositing at least two layers of spacer material on the substrate and patterning the at least two layers of the spacer material such that spacers in the second set of spacers include material from a greater number of layers of spacer material than the spacers in the first set of spacers. In some implementations, forming the first and second sets of spacers includes encapsulating a plurality of polymer protrusions in at least one of a metal and a semiconductor. In some other implementations, forming the first and second sets of spacers includes encapsulating a plurality of polymer protrusions in a conductive material.

Another innovative aspect of the subject matter described in this disclosure can be implemented in a display apparatus. The display apparatus includes an array of image formation means for outputting a plurality of image pixels, a plurality of first spacing means for maintaining at least a first distance between the image formation means and an opposing substrate, and a plurality of second spacing means for maintaining at least a second distance between the image formation means and the opposing substrate. The second distance is greater than the first distance. At least one of the first spacing means is positioned between at least two second spacing means. In some implementations, at least one of the first and second spacing means includes means for maintaining at least a portion of the image formation means at a common potential as a component formed on the opposing substrate.

In some implementations, the image formation means includes means for modulating light output by a backlight. In some other implementations, image formation means includes means for selectively emitting light.

Details of one or more implementations of the subject matter described in this specification are set forth in the accompanying drawings and the description below. Although the examples provided in this summary are primarily described in terms of MEMS-based displays, the concepts provided herein may apply to other types of displays, such as liquid crystal (LCD) displays, organic light emitting diode (OLED) displays, electrophoretic displays, and field emission displays, as well as to other non-display MEMS devices, such as MEMS microphones, sensors, and optical switches. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1A shows an example schematic diagram of a direct-view microelectromechanical systems (MEMS)-based display apparatus.

FIG. 1B shows an example block diagram of a host device.

FIG. 2A shows an example perspective view of an illustrative shutter-based light modulator.

FIG. 2B shows a cross sectional view of a rolling actuator shutter-based light modulator.

FIG. 2C shows a cross sectional view of an illustrative non shutter-based MEMS light modulator.

FIG. 2D shows a cross sectional view of an electrowetting-based light modulation array.

FIG. 3A shows an example schematic diagram of a control matrix.

FIG. 3B shows a perspective view of an array of shutter-based light modulators connected to the control matrix of FIG. 3A.

FIGS. 4A and 4B show example views of a dual actuator shutter assembly.

FIG. 5 shows an example cross sectional view of a display apparatus incorporating shutter-based light modulators.

FIG. 6 shows a cross sectional view of a light modulator substrate and an aperture plate for use in a MEMS-down configuration of a display.

FIG. 7 shows a flow diagram of a fabrication process for simultaneously fabricating spacers and anchors on a substrate for use in a display apparatus.

FIGS. 8A-8G show cross sectional views of stages of construction of an example spacer and anchor assembly using the fabrication process of FIG. 7.

FIG. 9 shows an example cross sectional view of an alternate configuration of an anchor and shutter assembly.

FIG. 10 shows an example cross sectional view of another alternate configuration of an anchor and shutter assembly.

FIGS. 11A and 11B show example cross sectional views of two anchor and shutter assemblies.

FIG. 12 shows an example cross sectional view of an anchor and separate spacer formed on a substrate by a single fabrication process.

FIG. 13 is a cross sectional view of a display apparatus.

FIGS. 14A and 14B show cross sections of a display apparatus at two ambient temperatures.

FIGS. 15A and 15B show cross sections of a display apparatus at two ambient temperatures.

FIGS. 16A-16D show example arrangements of spacer pairs having varying component heights.

FIG. 17 shows a portion of a display apparatus.

FIG. 18 shows a flow diagram of a method of forming a plurality of spacers.

FIGS. 19A-19G show various stages of a process for manufacturing multi-height spacer components in a display assembly.

FIGS. 20A-20E show various stages of an alternative process for manufacturing multi-height spacer components in a display assembly.

FIG. 21 shows a portion of a display apparatus having conductive spacers.

FIGS. 22A and 22B are system block diagrams illustrating a display device that includes a plurality of display elements.

Like reference numbers and designations in the various drawings indicate like elements.

### DETAILED DESCRIPTION

This disclosure relates to the fabrication of electromechanical systems (EMS) spacer structures for use in display apparatus. More particularly, the disclosure relates to multi-height EMS spacers and conductive spacers. The spacers can be nanoelectromechancial systems (NEMS), microelectromechanical systems (MEMS), or larger scale spacers. The spacers keep opposing substrates in the display apparatus at least a predetermined distance away from one another. In some implementations, the spacers disclosed herein can be manufactured as part of the same fabrication process used to fabricate EMS light modulators included in the display apparatus. In some other implementations the EMS spacers disclosed herein are configured to maintain a gap between substrates in other forms of displays, such as liquid (LCD) crystal displays, organic light emitting diode (OLED) displays, electrophoretic displays, and field emission displays, as well as to other non-display EMS devices, such as EMS microphones, sensors, and optical switches.

In some implementations, multi-height spacers are fabricated from two or more layers of patterned polymer material encapsulated in a structure material used to form EMS light modulators. In some implementations, some of the spacers include fewer layers of polymer material and thus are shorter than the spacers including additional layers of polymer material. In some other implementations, at least one of the polymer layers used to form the multi-height spacers is patterned using a half-tone or grayscale mask, resulting in spacer portions in that polymer layer having different heights.

In some implementations, the multi-height spacers make up portions of a set of multi-component spacers. For example, the multi-height spacers form lower-spacer components and opposing spacers extending from an opposing substrate form upper-spacer components. In some other implementations, the multi-height spacers form upper-spacer components and opposing spacers extending from an opposing substrate form lower-spacer components.

In some implementations, a shorter set of the multi-height spacers are arranged at the interior of the display apparatus and a taller set of the multi-height spacers are arranged at the perimeter of the display. In some implementations, groups of taller spacers are located in one or more locations within the interior of the display as well as at the perimeter. These groups of taller spacers are separated by at least one group of shorter spacers. In some implementations, the taller spacers are configured to serve as fluid barriers to prevent fluid flow or pressure waves through the fluid to damage light modulators positioned behind the fluid barriers.

In some implementations, the structural material used to encapsulate the spacers is conductive. The proximal end of these conductive spacers are electrically coupled to an anchor supporting a corresponding EMS display element, such an EMS light modulator. The distal end of the spacers electrically couple to a conductive surface deposited on an opposing substrate to maintain a movable portion of the EMS display element, such as a shutter, at a common potential with the conductive surface.

Particular implementations of the subject matter described in this disclosure can be implemented to realize one or more of the following potential advantages. Display apparatus substrates that seal in a liquid may deform to various degrees under varying ambient operating temperatures. Such deformation can help prevent the formation of bubbles. However, extensive, localized deformation can result in undesirable image artifacts. These artifacts can be mitigated by distributing the deformation of a substrate across its surface, resulting in an increased number of less detectable deformations. Incorporation of multi-height spacers in an EMS display apparatus allows for varying levels of deformation across the display apparatus.

By fabricating the multi-height spacers using the same fabrication steps used in constructing the display elements of a display, the spacers can be created with few or no additional processing steps, reducing the cost of adding the feature. These processes yield strong, durable spacers that can maintain at least a predetermined gap between opposing display substrates.

Conductive spacers yield the added benefit of being able to reduce or eliminate any voltage differential between moving portions of the display elements and conductive materials deposited on an opposing substrate. Reducing this voltage differential mitigates the risk of the movable components being attracted towards the opposing substrate, and possibly permanently adhering to the opposing substrate.

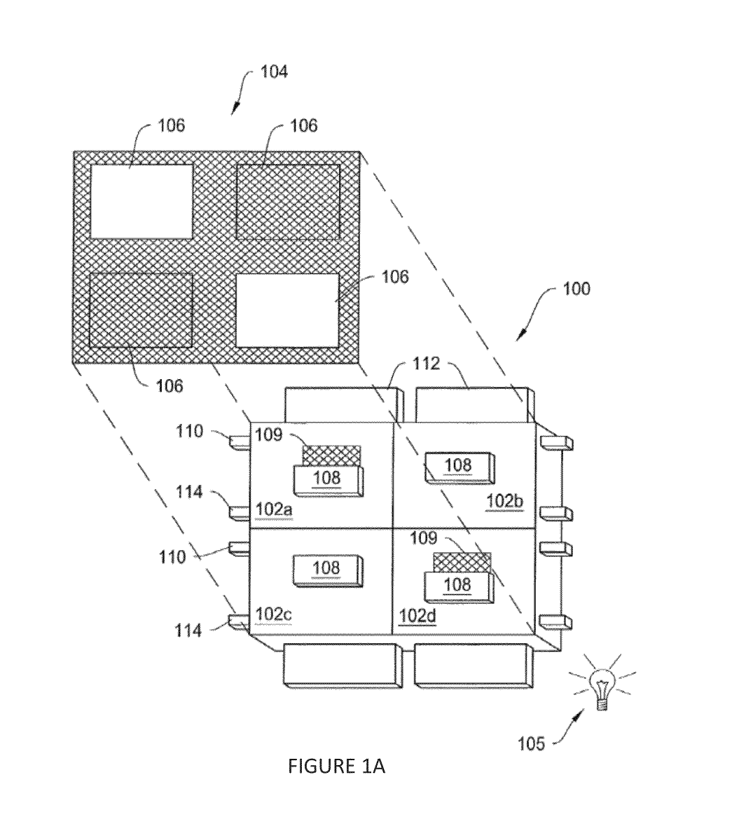

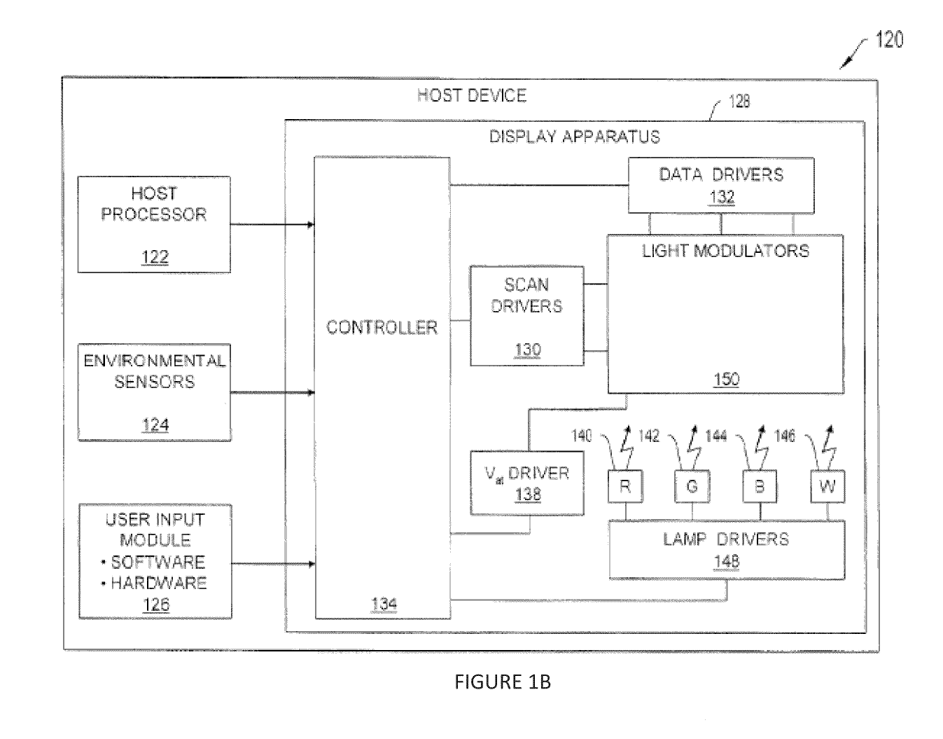

FIG. 1A shows a schematic diagram of a direct-view MEMS-based display apparatus 100. The display apparatus 100 includes a plurality of light modulators 102a-102d (generally “light modulators 102”) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide luminance level in an image 104. With respect to an image, a “pixel” corresponds to the smallest picture element defined by the resolution of image. With respect to structural components of the display apparatus 100, the term “pixel” refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the user sees the image by looking directly at the display apparatus, which contains the light modulators and optionally a backlight or front light for enhancing brightness and/or contrast seen on the display.

Direct-view displays may operate in either a transmissive or reflective mode. In a transmissive display, the light modulators filter or selectively block light which originates from a lamp or lamps positioned behind the display. The light from the lamps is optionally injected into a light guide or “backlight” so that each pixel can be uniformly illuminated. Transmissive direct-view displays are often built onto transparent or glass substrates to facilitate a sandwich assembly arrangement where one substrate, containing the light modulators, is positioned directly on top of the backlight.

Each light modulator 102 can include a shutter 108 and an aperture 109. To illuminate a pixel 106 in the image 104, the shutter 108 is positioned such that it allows light to pass through the aperture 109 towards a viewer. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix connected to the substrate and to the light modulators for controlling the movement of the shutters. The control matrix includes a series of electrical interconnects (e.g., interconnects 110, 112 and 114), including at least one write-enable interconnect 110 (also referred to as a “scan-line interconnect”) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the “write-enabling voltage, V_{WE}”), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, e.g., transistors or other non-linear circuit elements that control the application of separate actuation voltages, which are typically higher in magnitude than the data voltages, to the light modulators 102. The application of these actuation voltages then results in the electrostatic driven movement of the shutters 108.

FIG. 1B shows an example of a block diagram of a host device 120 (i.e., cell phone, smart phone, PDA, MP3 player, tablet, e-reader, etc.). The host device 120 includes a display apparatus 128, a host processor 122, environmental sensors 124, a user input module 126, and a power source.

The display apparatus 128 includes a plurality of scan drivers 130 (also referred to as “write enabling voltage sources”), a plurality of data drivers 132 (also referred to as “data voltage sources”), a controller 134, common drivers 138, lamps 140-146, lamp drivers 148 and an array 150 of display elements, such as the light modulators 102 shown in FIG. 1A. The scan drivers 130 apply write enabling voltages to scan-line interconnects 110. The data drivers 132 apply data voltages to the data interconnects 112.

In some implementations of the display apparatus, the data drivers 132 are configured to provide analog data voltages to the array 150 of display elements, especially where the luminance level of the image 104 is to be derived in analog fashion. In analog operation, the light modulators 102 are designed such that when a range of intermediate voltages is applied through the data interconnects 112, there results a range of intermediate open states in the shutters 108 and therefore a range of intermediate illumination states or luminance levels in the image 104. In other cases, the data drivers 132 are configured to apply only a reduced set of 2, 3 or 4 digital voltage levels to the data interconnects 112. These voltage levels are designed to set, in digital fashion, an open state, a closed state, or other discrete state to each of the shutters 108.

The scan drivers 130 and the data drivers 132 are connected to a digital controller circuit 134 (also referred to as the “controller 134”). The controller sends data to the data drivers 132 in a mostly serial fashion, organized in predetermined sequences grouped by rows and by image frames. The data drivers 132 can include series to parallel data converters, level shifting, and for some applications digital to analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 114. In some other implementations, the common drivers 138, following commands from the controller 134, issue voltage pulses or signals to the array 150 of display elements, for instance global actuation pulses which are capable of driving and/or initiating simultaneous actuation of all display elements in multiple rows and columns of the array 150.

All of the drivers (e.g., scan drivers 130, data drivers 132 and common drivers 138) for different display functions are time-synchronized by the controller 134. Timing commands from the controller coordinate the illumination of red, green and blue and white lamps (140, 142, 144 and 146 respectively) via lamp drivers 148, the write-enabling and sequencing of specific rows within the array 150 of display elements, the output of voltages from the data drivers 132, and the output of voltages that provide for display element actuation.

The controller 134 determines the sequencing or addressing scheme by which each of the shutters 108 can be re-set to the illumination levels appropriate to a new image 104. New images 104 can be set at periodic intervals. For instance, for video displays, the color images 104 or frames of video are refreshed at frequencies ranging from 10 to 300 Hertz (Hz). In some implementations the setting of an image frame to the array 150 is synchronized with the illumination of the lamps 140, 142, 144 and 146 such that alternate image frames are illuminated with an alternating series of colors, such as red, green, and blue. The image frames for each respective color is referred to as a color subframe. In this method, referred to as the field sequential color method, if the color subframes are alternated at frequencies in excess of 20 Hz, the human brain will average the alternating frame images into the perception of an image having a broad and continuous range of colors. In alternate implementations, four or more lamps with primary colors can be employed in display apparatus 100, employing primaries other than red, green, and blue.

In some implementations, where the display apparatus 100 is designed for the digital switching of shutters 108 between open and closed states, the controller 134 forms an image by the method of time division gray scale, as previously described. In some other implementations, the display apparatus 100 can provide gray scale through the use of multiple shutters 108 per pixel.

In some implementations, the data for an image state 104 is loaded by the controller 134 to the display element array 150 by a sequential addressing of individual rows, also referred to as scan lines. For each row or scan line in the sequence, the scan driver 130 applies a write-enable voltage to the write enable interconnect 110 for that row of the array 150, and subsequently the data driver 132 supplies data voltages, corresponding to desired shutter states, for each column in the selected row. This process repeats until data has been loaded for all rows in the array 150. In some implementations, the sequence of selected rows for data loading is linear, proceeding from top to bottom in the array 150. In some other implementations, the sequence of selected rows is pseudo-randomized, in order to minimize visual artifacts. And in some other implementations the sequencing is organized by blocks, where, for a block, the data for only a certain fraction of the image state 104 is loaded to the array 150, for instance by addressing only every 5^{th} row of the array 150 in sequence.

In some implementations, the process for loading image data to the array 150 is separated in time from the process of actuating the display elements in the array 150. In these implementations, the display element array 150 may include data memory elements for each display element in the array 150 and the control matrix may include a global actuation interconnect for carrying trigger signals, from common driver 138, to initiate simultaneous actuation of shutters 108 according to data stored in the memory elements.

In alternative implementations, the array 150 of display elements and the control matrix that controls the display elements may be arranged in configurations other than rectangular rows and columns. For example, the display elements can be arranged in hexagonal arrays or curvilinear rows and columns. In general, as used herein, the term scan-line shall refer to any plurality of display elements that share a write-enabling interconnect.

The host processor 122 generally controls the operations of the host. For example, the host processor 122 may be a general or special purpose processor for controlling a portable electronic device. With respect to the display apparatus 128, included within the host device 120, the host processor 122 outputs image data as well as additional data about the host. Such information may include data from environmental sensors, such as ambient light or temperature; information about the host, including, for example, an operating mode of the host or the amount of power remaining in the host's power source; information about the content of the image data; information about the type of image data; and/or instructions for display apparatus for use in selecting an imaging mode.

The user input module 126 conveys the personal preferences of the user to the controller 134, either directly, or via the host processor 122. In some implementations, the user input module 126 is controlled by software in which the user programs personal preferences such as “deeper color,” “better contrast,” “lower power,” “increased brightness,” “sports,” “live action,” or “animation.” In some other implementations, these preferences are input to the host using hardware, such as a switch or dial. The plurality of data inputs to the controller 134 direct the controller to provide data to the various drivers 130, 132, 138 and 148 which correspond to optimal imaging characteristics.

An environmental sensor module 124 also can be included as part of the host device 120. The environmental sensor module 124 receives data about the ambient environment, such as temperature and or ambient lighting conditions. The sensor module 124 can be programmed to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

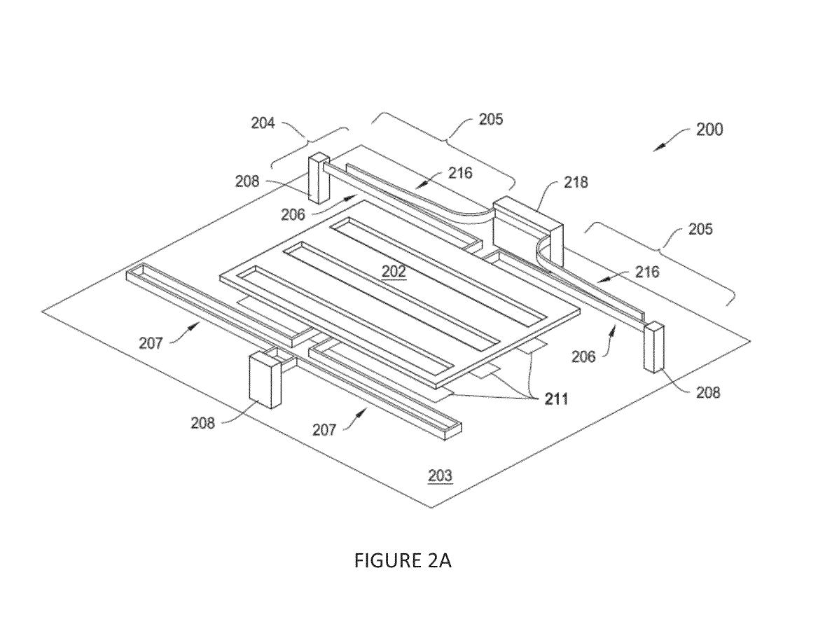

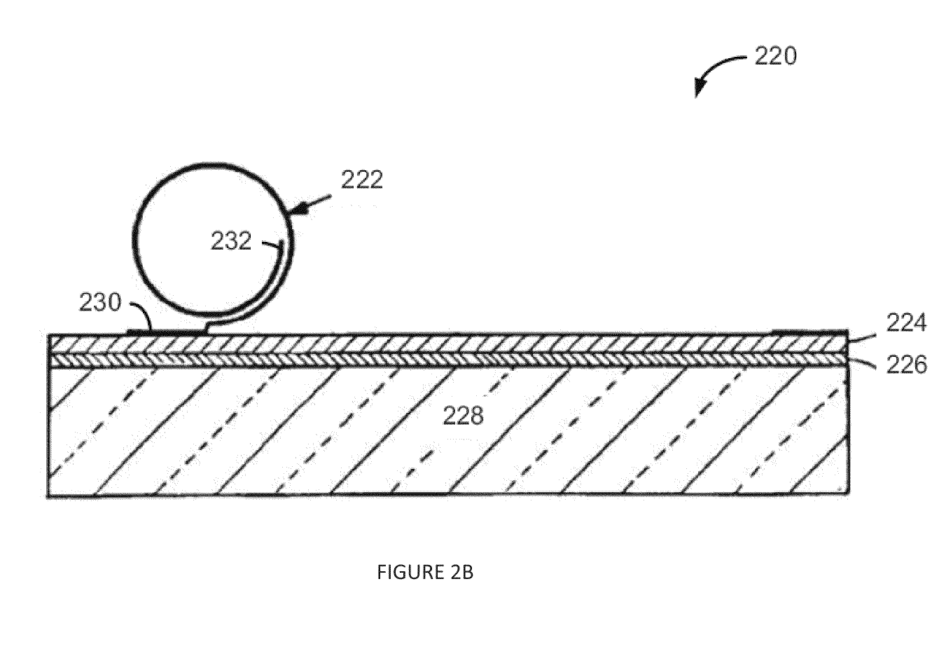

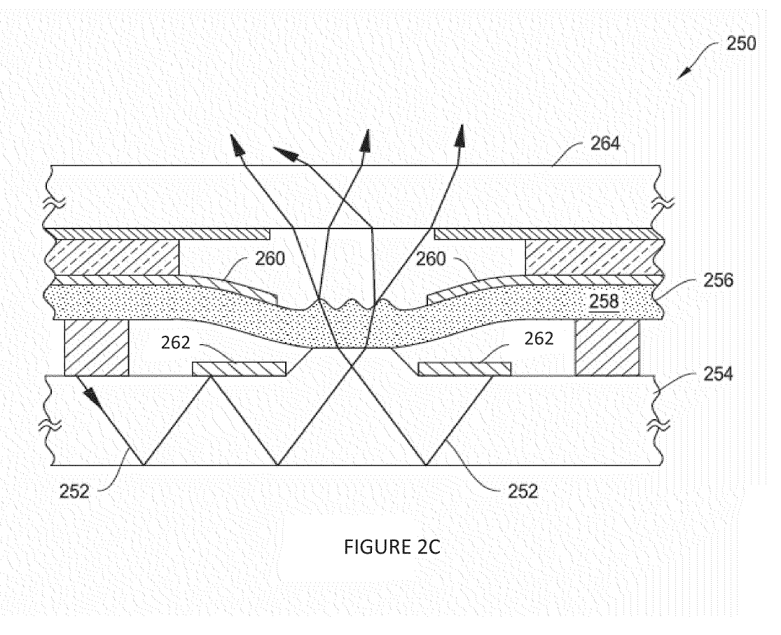

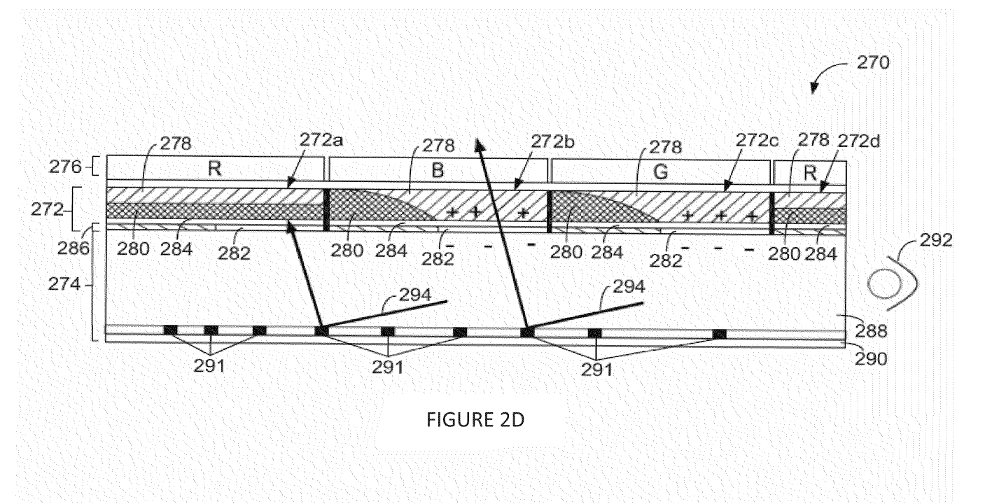

FIG. 2A shows a perspective view of an illustrative shutter-based light modulator 200. The shutter-based light modulator 200 is suitable for incorporation into the direct-view MEMS-based display apparatus 100 of FIG. 1A. The light modulator 200 includes a shutter 202 coupled to an actuator 204. The actuator 204 can be formed from two separate compliant electrode beam actuators 205 (the “actuators 205”). The shutter 202 couples on one side to the actuators 205. The actuators 205 move the shutter 202 transversely over a surface 203 in a plane of motion which is substantially parallel to the surface 203. The opposite side of the shutter 202 couples to a spring 207 which provides a restoring force opposing the forces exerted by the actuator 204.

Each actuator 205 includes a compliant load beam 206 connecting the shutter 202 to a load anchor 208. The load anchors 208 along with the compliant load beams 206 serve as mechanical supports, keeping the shutter 202 suspended proximate to the surface 203. The surface 203 includes one or more aperture holes 211 for admitting the passage of light. The load anchors 208 physically connect the compliant load beams 206 and the shutter 202 to the surface 203 and electrically connect the load beams 206 to a bias voltage, in some instances, ground.

If the substrate is opaque, such as silicon, then aperture holes 211 are formed in the substrate by etching an array of holes through the substrate 204. If the substrate 204 is transparent, such as glass or plastic, then the aperture holes 211 are formed in a layer of light-blocking material deposited on the substrate 203. The aperture holes 211 can be generally circular, elliptical, polygonal, serpentine, or irregular in shape.

Each actuator 205 also includes a compliant drive beam 216 positioned adjacent to each load beam 206. The drive beams 216 couple at one end to a drive beam anchor 218 shared between the drive beams 216. The other end of each drive beam 216 is free to move. Each drive beam 216 is curved such that it is closest to the load beam 206 near the free end of the drive beam 216 and the anchored end of the load beam 206.

In operation, a display apparatus incorporating the light modulator 200 applies an electric potential to the drive beams 216 via the drive beam anchor 218. A second electric potential may be applied to the load beams 206. The resulting potential difference between the drive beams 216 and the load beams 206 pulls the free ends of the drive beams 216 towards the anchored ends of the load beams 206, and pulls the shutter ends of the load beams 206 toward the anchored ends of the drive beams 216, thereby driving the shutter 202 transversely toward the drive anchor 218. The compliant members 206 act as springs, such that when the voltage across the beams 206 and 216 potential is removed, the load beams 206 push the shutter 202 back into its initial position, releasing the stress stored in the load beams 206.

A light modulator, such as the light modulator 200, incorporates a passive restoring force, such as a spring, for returning a shutter to its rest position after voltages have been removed. Other shutter assemblies can incorporate a dual set of “open” and “closed” actuators and a separate set of “open” and “closed” electrodes for moving the shutter into either an open or a closed state.

There are a variety of methods by which an array of shutters and apertures can be controlled via a control matrix to produce images, in many cases moving images, with appropriate luminance levels. In some cases, control is accomplished by means of a passive matrix array of row and column interconnects connected to driver circuits on the periphery of the display. In other cases it is appropriate to include switching and/or data storage elements within each pixel of the array (the so-called active matrix) to improve the speed, the luminance level and/or the power dissipation performance of the display.

The display apparatus 100, in alternative implementations, includes display elements other than transverse shutter-based light modulators, such as the shutter assembly 200 described above. For example, FIG. 2B shows a cross sectional view of a rolling actuator shutter-based light modulator 220. The rolling actuator shutter-based light modulator 220 is suitable for incorporation into an alternative implementation of the MEMS-based display apparatus 100 of FIG. 1A. A rolling actuator-based light modulator includes a movable electrode disposed opposite a fixed electrode and biased to move in a particular direction to function as a shutter upon application of an electric field. In some implementations, the light modulator 220 includes a planar electrode 226 disposed between a substrate 228 and an insulating layer 224 and a movable electrode 222 having a fixed end 230 attached to the insulating layer 224. In the absence of any applied voltage, a movable end 232 of the movable electrode 222 is free to roll towards the fixed end 230 to produce a rolled state. Application of a voltage between the electrodes 222 and 226 causes the movable electrode 222 to unroll and lie flat against the insulating layer 224, whereby it acts as a shutter that blocks light traveling through the substrate 228. The movable electrode 222 returns to the rolled state by means of an elastic restoring force after the voltage is removed. The bias towards a rolled state may be achieved by manufacturing the movable electrode 222 to include an anisotropic stress state.

FIG. 2C shows a cross sectional view of an illustrative non shutter-based MEMS light modulator 250. The light tap modulator 250 is suitable for incorporation into an alternative implementation of the MEMS-based display apparatus 100 of FIG. 1A. A light tap works according to a principle of frustrated total internal reflection (TIR). That is, light 252 is introduced into a light guide 254, in which, without interference, light 252 is, for the most part, unable to escape the light guide 254 through its front or rear surfaces due to TIR. The light tap 250 includes a tap element 256 that has a sufficiently high index of refraction that, in response to the tap element 256 contacting the light guide 254, the light 252 impinging on the surface of the light guide 254 adjacent the tap element 256 escapes the light guide 254 through the tap element 256 towards a viewer, thereby contributing to the formation of an image.

In some implementations, the tap element 256 is formed as part of a beam 258 of flexible, transparent material. Electrodes 260 coat portions of one side of the beam 258. Opposing electrodes 262 are disposed on the light guide 254. By applying a voltage across the electrodes 260 and 262, the position of the tap element 256 relative to the light guide 254 can be controlled to selectively extract light 252 from the light guide 254.

FIG. 2D shows an example cross sectional view of an electrowetting-based light modulation array 270. The electrowetting-based light modulation array 270 is suitable for incorporation into an alternative implementation of the MEMS-based display apparatus 100 of FIG. 1A. The light modulation array 270 includes a plurality of electrowetting-based light modulation cells 272a-d (generally “cells 272”) formed on an optical cavity 274. The light modulation array 270 also includes a set of color filters 276 corresponding to the cells 272.

Each cell 272 includes a layer of water (or other transparent conductive or polar fluid) 278, a layer of light absorbing oil 280, a transparent electrode 282 (made, for example, from indium-tin oxide (ITO)) and an insulating layer 284 positioned between the layer of light absorbing oil 280 and the transparent electrode 282. In the implementation described herein, the electrode takes up a portion of a rear surface of a cell 272.

The remainder of the rear surface of a cell 272 is formed from a reflective aperture layer 286 that forms the front surface of the optical cavity 274. The reflective aperture layer 286 is formed from a reflective material, such as a reflective metal or a stack of thin films forming a dielectric mirror. For each cell 272, an aperture is formed in the reflective aperture layer 286 to allow light to pass through. The electrode 282 for the cell is deposited in the aperture and over the material forming the reflective aperture layer 286, separated by another dielectric layer.

The remainder of the optical cavity 274 includes a light guide 288 positioned proximate the reflective aperture layer 286, and a second reflective layer 290 on a side of the light guide 288 opposite the reflective aperture layer 286. A series of light redirectors 291 are formed on the rear surface of the light guide, proximate the second reflective layer. The light redirectors 291 may be either diffuse or specular reflectors. One or more light sources 292, such as LEDs, inject light 294 into the light guide 288.

In an alternative implementation, an additional transparent substrate (not shown) is positioned between the light guide 288 and the light modulation array 270. In this implementation, the reflective aperture layer 286 is formed on the additional transparent substrate instead of on the surface of the light guide 288.

In operation, application of a voltage to the electrode 282 of a cell (for example, cell 272b or 272c) causes the light absorbing oil 280 in the cell to collect in one portion of the cell 272. As a result, the light absorbing oil 280 no longer obstructs the passage of light through the aperture formed in the reflective aperture layer 286 (see, for example, cells 272b and 272c). Light escaping the backlight at the aperture is then able to escape through the cell and through a corresponding color filter (for example, red, green or blue) in the set of color filters 276 to form a color pixel in an image. When the electrode 282 is grounded, the light absorbing oil 280 covers the aperture in the reflective aperture layer 286, absorbing any light 294 attempting to pass through it.

The area under which oil 280 collects when a voltage is applied to the cell 272 constitutes wasted space in relation to forming an image. This area is non-transmissive, whether a voltage is applied or not. Therefore, without the inclusion of the reflective portions of reflective apertures layer 286, this area absorbs light that otherwise could be used to contribute to the formation of an image. However, with the inclusion of the reflective aperture layer 286, this light, which otherwise would have been absorbed, is reflected back into the light guide 290 for future escape through a different aperture. The electrowetting-based light modulation array 270 is not the only example of a non-shutter-based MEMS modulator suitable for inclusion in the display apparatus described herein. Other forms of non-shutter-based MEMS modulators could likewise be controlled by various ones of the controller functions described herein without departing from the scope of this disclosure.

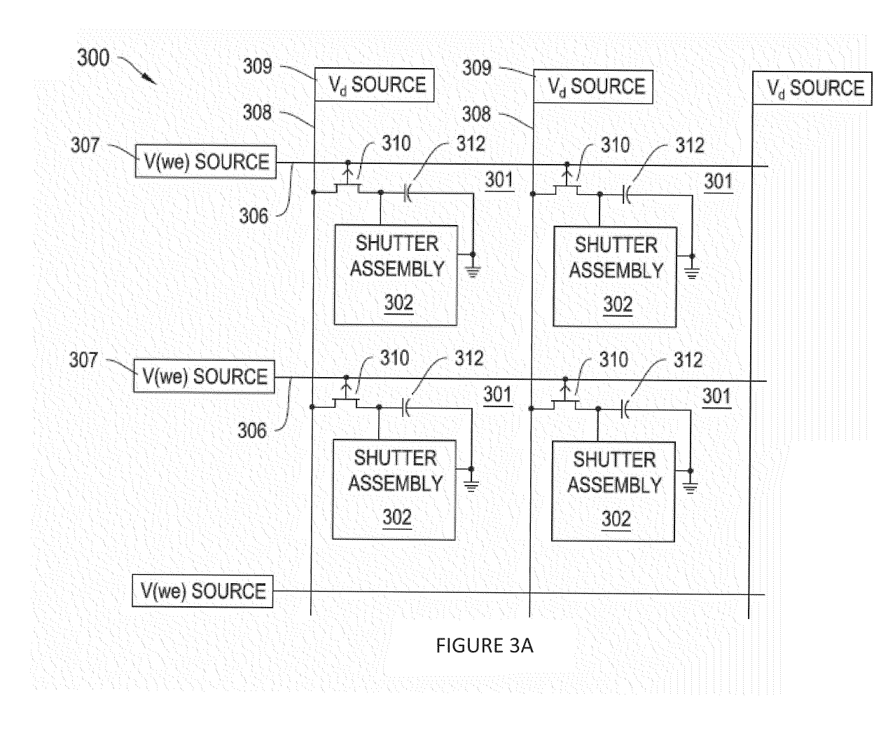

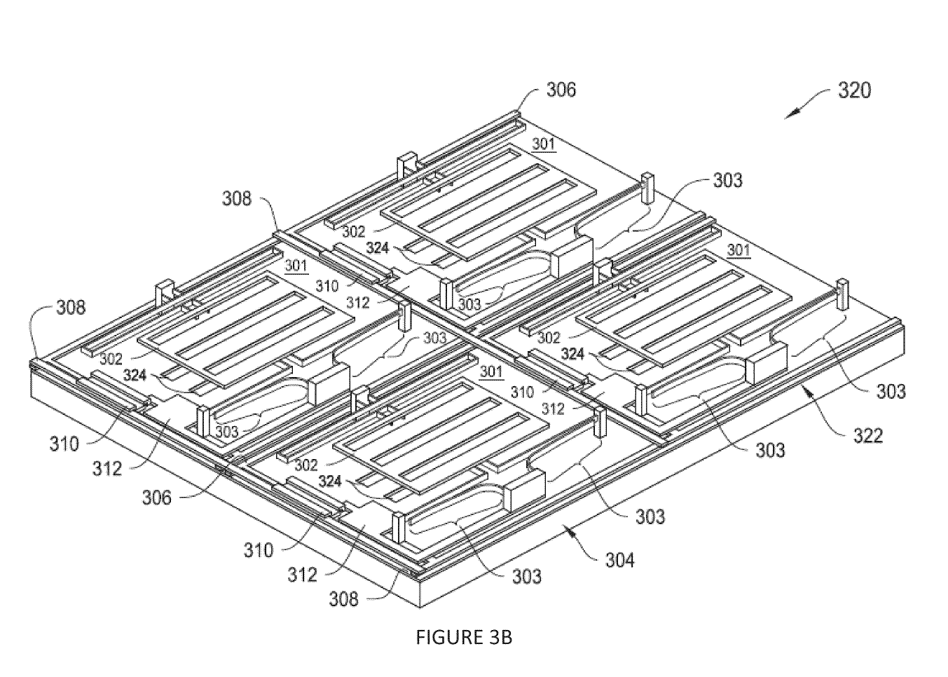

FIG. 3A shows an example schematic diagram of a control matrix 300. The control matrix 300 is suitable for controlling the light modulators incorporated into the MEMS-based display apparatus 100 of FIG. 1A. FIG. 3B shows a perspective view of an array 320 of shutter-based light modulators connected to the control matrix 300 of FIG. 3A. The control matrix 300 may address an array of pixels 320 (the “array 320”). Each pixel 301 can include an elastic shutter assembly 302, such as the shutter assembly 200 of FIG. 2A, controlled by an actuator 303. Each pixel also can include an aperture layer 322 that includes apertures 324.

The control matrix 300 is fabricated as a diffused or thin-film-deposited electrical circuit on the surface of a substrate 304 on which the shutter assemblies 302 are formed. The control matrix 300 includes a scan-line interconnect 306 for each row of pixels 301 in the control matrix 300 and a data-interconnect 308 for each column of pixels 301 in the control matrix 300. Each scan-line interconnect 306 electrically connects a write-enabling voltage source 307 to the pixels 301 in a corresponding row of pixels 301. Each data interconnect 308 electrically connects a data voltage source 309 (“V_{d} source”) to the pixels 301 in a corresponding column of pixels. In the control matrix 300, the V_{d} source 309 provides the majority of the energy to be used for actuation of the shutter assemblies 302. Thus, the data voltage source, V_{d} source 309, also serves as an actuation voltage source.

Referring to FIGS. 3A and 3B, for each pixel 301 or for each shutter assembly 302 in the array of pixels 320, the control matrix 300 includes a transistor 310 and a capacitor 312. The gate of each transistor 310 is electrically connected to the scan-line interconnect 306 of the row in the array 320 in which the pixel 301 is located. The source of each transistor 310 is electrically connected to its corresponding data interconnect 308. The actuators 303 of each shutter assembly 302 include two electrodes. The drain of each transistor 310 is electrically connected in parallel to one electrode of the corresponding capacitor 312 and to one of the electrodes of the corresponding actuator 303. The other electrode of the capacitor 312 and the other electrode of the actuator 303 in shutter assembly 302 are connected to a common or ground potential. In alternate implementations, the transistors 310 can be replaced with semiconductor diodes and or metal-insulator-metal sandwich type switching elements.

In operation, to form an image, the control matrix 300 write-enables each row in the array 320 in a sequence by applying V_{we} to each scan-line interconnect 306 in turn. For a write-enabled row, the application of V_{we} to the gates of the transistors 310 of the pixels 301 in the row allows the flow of current through the data interconnects 308 through the transistors 310 to apply a potential to the actuator 303 of the shutter assembly 302. While the row is write-enabled, data voltages V_{d} are selectively applied to the data interconnects 308. In implementations providing analog gray scale, the data voltage applied to each data interconnect 308 is varied in relation to the desired brightness of the pixel 301 located at the intersection of the write-enabled scan-line interconnect 306 and the data interconnect 308. In implementations providing digital control schemes, the data voltage is selected to be either a relatively low magnitude voltage (i.e., a voltage near ground) or to meet or exceed Vₐₜ (the actuation threshold voltage). In response to the application of Vₐₜ to a data interconnect 308, the actuator 303 in the corresponding shutter assembly actuates, opening the shutter in that shutter assembly 302. The voltage applied to the data interconnect 308 remains stored in the capacitor 312 of the pixel 301 even after the control matrix 300 ceases to apply V, to a row. Therefore, the voltage V_{we} does not have to wait and hold on a row for times long enough for the shutter assembly 302 to actuate; such actuation can proceed after the write-enabling voltage has been removed from the row. The capacitors 312 also function as memory elements within the array 320, storing actuation instructions for the illumination of an image frame.

The pixels 301 as well as the control matrix 300 of the array 320 are formed on a substrate 304. The array 320 includes an aperture layer 322, disposed on the substrate 304, which includes a set of apertures 324 for respective pixels 301 in the array 320. The apertures 324 are aligned with the shutter assemblies 302 in each pixel. In some implementations, the substrate 304 is made of a transparent material, such as glass or plastic. In some other implementations, the substrate 304 is made of an opaque material, but in which holes are etched to form the apertures 324.

The shutter assembly 302 together with the actuator 303 can be made bi-stable. That is, the shutters can exist in at least two equilibrium positions (e.g., open or closed) with little or no power required to hold them in either position. More particularly, the shutter assembly 302 can be mechanically bi-stable. Once the shutter of the shutter assembly 302 is set in position, no electrical energy or holding voltage is required to maintain that position. The mechanical stresses on the physical elements of the shutter assembly 302 can hold the shutter in place.

The shutter assembly 302 together with the actuator 303 also can be made electrically bi-stable. In an electrically bi-stable shutter assembly, there exists a range of voltages below the actuation voltage of the shutter assembly, which if applied to a closed actuator (with the shutter being either open or closed), holds the actuator closed and the shutter in position, even if an opposing force is exerted on the shutter. The opposing force may be exerted by a spring such as the spring 207 in the shutter-based light modulator 200 depicted in FIG. 2A, or the opposing force may be exerted by an opposing actuator, such as an “open” or “closed” actuator.

The light modulator array 320 is depicted as having a single MEMS light modulator per pixel. Other implementations are possible in which multiple MEMS light modulators are provided in each pixel, thereby providing the possibility of more than just binary “on” or “off” optical states in each pixel. Certain forms of coded area division gray scale are possible where multiple MEMS light modulators in the pixel are provided, and where apertures 324, which are associated with each of the light modulators, have unequal areas.

In some other implementations, the roller-based light modulator 220, the light tap 250, or the electrowetting-based light modulation array 270, as well as other MEMS-based light modulators, can be substituted for the shutter assembly 302 within the light modulator array 320.

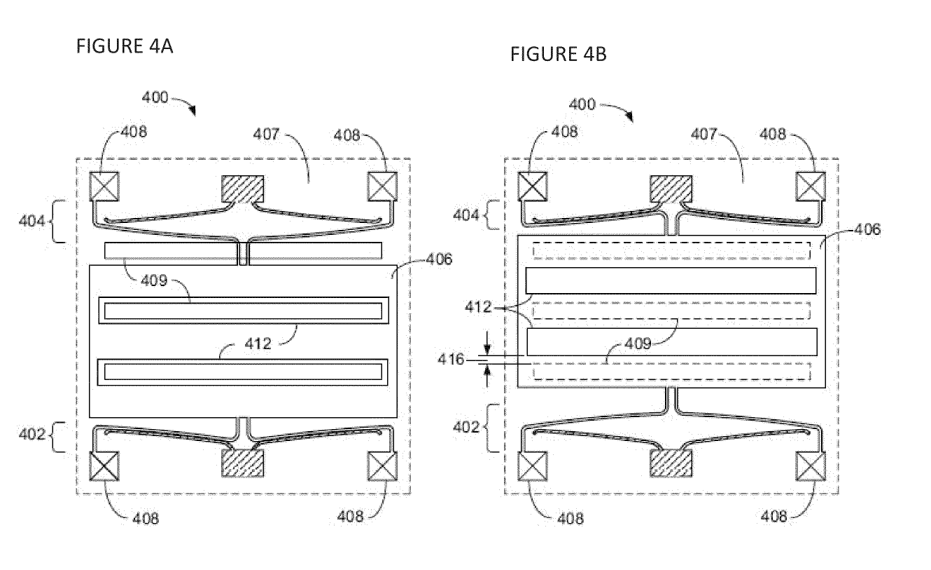

FIGS. 4A and 4B show example views of a dual actuator shutter assembly 400. The dual actuator shutter assembly 400, as depicted in FIG. 4A, is in an open state. FIG. 4B shows the dual actuator shutter assembly 400 in a closed state. In contrast to the shutter assembly 200, the shutter assembly 400 includes actuators 402 and 404 on either side of a shutter 406. Each actuator 402 and 404 is independently controlled. A first actuator, a shutter-open actuator 402, serves to open the shutter 406. A second opposing actuator, the shutter-close actuator 404, serves to close the shutter 406. Both of the actuators 402 and 404 are compliant beam electrode actuators. The actuators 402 and 404 open and close the shutter 406 by driving the shutter 406 substantially in a plane parallel to an aperture layer 407 over which the shutter is suspended. The shutter 406 is suspended a short distance over the aperture layer 407 by anchors 408 attached to the actuators 402 and 404. The inclusion of supports attached to both ends of the shutter 406 along its axis of movement reduces out of plane motion of the shutter 406 and confines the motion substantially to a plane parallel to the substrate. By analogy to the control matrix 300 of FIG. 3A, a control matrix suitable for use with the shutter assembly 400 might include one transistor and one capacitor for each of the opposing shutter-open and shutter-close actuators 402 and 404.

The shutter 406 includes two shutter apertures 412 through which light can pass. The aperture layer 407 includes a set of three apertures 409. In FIG. 4A, the shutter assembly 400 is in the open state and, as such, the shutter-open actuator 402 has been actuated, the shutter-close actuator 404 is in its relaxed position, and the centerlines of the shutter apertures 412 coincide with the centerlines of two of the aperture layer apertures 409. In FIG. 4B the shutter assembly 400 has been moved to the closed state and, as such, the shutter-open actuator 402 is in its relaxed position, the shutter-close actuator 404 has been actuated, and the light blocking portions of the shutter 406 are now in position to block transmission of light through the apertures 409 (depicted as dotted lines).

Each aperture has at least one edge around its periphery. For example, the rectangular apertures 409 have four edges. In alternative implementations in which circular, elliptical, oval, or other curved apertures are formed in the aperture layer 407, each aperture may have only a single edge. In some other implementations, the apertures need not be separated or disjoint in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through apertures 412 and 409 in the open state, it is advantageous to provide a width or size for shutter apertures 412 which is larger than a corresponding width or size of apertures 409 in the aperture layer 407. In order to effectively block light from escaping in the closed state, it is preferable that the light blocking portions of the shutter 406 overlap the apertures 409. FIG. 4B shows a predefined overlap 416 between the edge of light blocking portions in the shutter 406 and one edge of the aperture 409 formed in the aperture layer 407.

The electrostatic actuators 402 and 404 are designed so that their voltage-displacement behavior provides a bi-stable characteristic to the shutter assembly 400. For each of the shutter-open and shutter-close actuators there exists a range of voltages below the actuation voltage, which if applied while that actuator is in the closed state (with the shutter being either open or closed), will hold the actuator closed and the shutter in position, even after an actuation voltage is applied to the opposing actuator. The minimum voltage needed to maintain a shutter's position against such an opposing force is referred to as a maintenance voltage Vₘ.

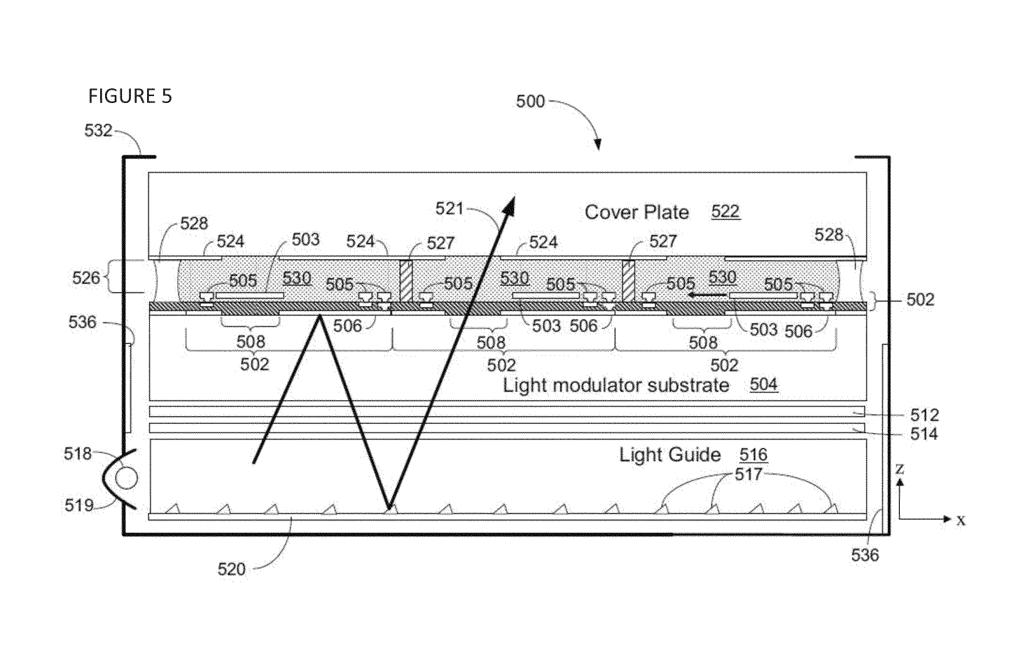

FIG. 5 shows an example cross sectional view of a display apparatus 500 incorporating shutter-based light modulators (shutter assemblies) 502. Each shutter assembly 502 incorporates a shutter 503 and an anchor 505. Not shown are the compliant beam actuators which, when connected between the anchors 505 and the shutters 503, help to suspend the shutters 503 a short distance above the surface. The shutter assemblies 502 are disposed on a transparent substrate 504, such a substrate made of plastic or glass. A rear-facing reflective layer, reflective film 506, disposed on the substrate 504 defines a plurality of surface apertures 508 located beneath the closed positions of the shutters 503 of the shutter assemblies 502. The reflective film 506 reflects light not passing through the surface apertures 508 back towards the rear of the display apparatus 500. The reflective aperture layer 506 can be a fine-grained metal film without inclusions formed in thin film fashion by a number of vapor deposition techniques including sputtering, evaporation, ion plating, laser ablation, or chemical vapor deposition (CVD). In some other implementations, the rear-facing reflective layer 506 can be formed from a mirror, such as a dielectric mirror. A dielectric mirror can be fabricated as a stack of dielectric thin films which alternate between materials of high and low refractive index. The vertical gap which separates the shutters 503 from the reflective film 506, within which the shutter is free to move, is in the range of 0.5 to 10 microns. The magnitude of the vertical gap is preferably less than the lateral overlap between the edge of shutters 503 and the edge of apertures 508 in the closed state, such as the overlap 416 depicted in FIG. 4B.

The display apparatus 500 includes an optional diffuser 512 and/or an optional brightness enhancing film 514 which separate the substrate 504 from a planar light guide 516. The light guide 516 includes a transparent, i.e., glass or plastic material. The light guide 516 is illuminated by one or more light sources 518, forming a backlight. The light sources 518 can be, for example, and without limitation, incandescent lamps, fluorescent lamps, lasers or light emitting diodes (LEDs). A reflector 519 helps direct light from lamp 518 towards the light guide 516. A front-facing reflective film 520 is disposed behind the backlight 516, reflecting light towards the shutter assemblies 502. Light rays such as ray 521 from the backlight that do not pass through one of the shutter assemblies 502 will be returned to the backlight and reflected again from the film 520. In this fashion light that fails to leave the display apparatus 500 to form an image on the first pass can be recycled and made available for transmission through other open apertures in the array of shutter assemblies 502. Such light recycling has been shown to increase the illumination efficiency of the display.

The light guide 516 includes a set of geometric light redirectors or prisms 517 which re-direct light from the lamps 518 towards the apertures 508 and hence toward the front of the display. The light redirectors 517 can be molded into the plastic body of light guide 516 with shapes that can be alternately triangular, trapezoidal, or curved in cross section. The density of the prisms 517 generally increases with distance from the lamp 518.

In some implementations, the aperture layer 506 can be made of a light absorbing material, and in alternate implementations the surfaces of shutter 503 can be coated with either a light absorbing or a light reflecting material. In some other implementations, the aperture layer 506 can be deposited directly on the surface of the light guide 516. In some implementations, the aperture layer 506 need not be disposed on the same substrate as the shutters 503 and anchors 505 (such as in the MEMS-down configuration described below).

In some implementations, the light sources 518 can include lamps of different colors, for instance, the colors red, green and blue. A color image can be formed by sequentially illuminating images with lamps of different colors at a rate sufficient for the human brain to average the different colored images into a single multi-color image. The various color-specific images are formed using the array of shutter assemblies 502. In another implementation, the light source 518 includes lamps having more than three different colors. For example, the light source 518 may have red, green, blue and white lamps, or red, green, blue and yellow lamps. In some other implementations, the light source 518 may include cyan, magenta, yellow and white lamps, red, green, blue and white lamps. In some other implementations, additional lamps may be included in the light source 518. For example, if using five colors, the light source 518 may include red, green, blue, cyan and yellow lamps. In some other implementations, the light source 518 may include white, orange, blue, purple and green lamps or white, blue, yellow, red and cyan lamps. If using six colors, the light source 518 may include red, green, blue, cyan, magenta and yellow lamps or white, cyan, magenta, yellow, orange and green lamps.

A cover plate 522 forms the front of the display apparatus 500. The rear side of the cover plate 522 can be covered with a black matrix 524 to increase contrast. In alternate implementations the cover plate includes color filters, for instance distinct red, green, and blue filters corresponding to different ones of the shutter assemblies 502. The cover plate 522 is supported a predetermined distance away from the shutter assemblies 502 forming a gap 526. The gap 526 is maintained by mechanical supports or spacers 527 and/or by an adhesive seal 528 attaching the cover plate 522 to the substrate 504.

The adhesive seal 528 seals in a fluid 530. The fluid 530 is engineered with viscosities preferably below about 10 centipoise and with relative dielectric constant preferably above about 2.0, and dielectric breakdown strengths above about 10⁴ V/cm. The fluid 530 also can serve as a lubricant. In some implementations, the fluid 530 is a hydrophobic liquid with a high surface wetting capability. In alternate implementations, the fluid 530 has a refractive index that is either greater than or less than that of the substrate 504.

Displays that incorporate mechanical light modulators can include hundreds, thousands, or in some cases, millions of moving elements. In some devices, every movement of an element provides an opportunity for static friction to disable one or more of the elements. This movement is facilitated by immersing all the parts in a fluid (also referred to as fluid 530) and sealing the fluid (e.g., with an adhesive) within a fluid space or gap in a MEMS display cell. The fluid 530 is usually one with a low coefficient of friction, low viscosity, and minimal degradation effects over the long term. When the MEMS-based display assembly includes a liquid for the fluid 530, the liquid at least partially surrounds some of the moving parts of the MEMS-based light modulator. In some implementations, in order to reduce the actuation voltages, the liquid has a viscosity below 70 centipoise. In some other implementations, the liquid has a viscosity below 10 centipoise. Liquids with viscosities below 70 centipoise can include materials with low molecular weights: below 4000 grams/mole, or in some cases below 400 grams/mole. Fluids 530 that also may be suitable for such implementations include, without limitation, de-ionized water, methanol, ethanol and other alcohols, paraffins, olefins, ethers, silicone oils, fluorinated silicone oils, or other natural or synthetic solvents or lubricants. Useful fluids can be polydimethylsiloxanes (PDMS), such as hexamethyldisiloxane and octamethyltrisiloxane, or alkyl methyl siloxanes such as hexylpentamethyldisiloxane. Useful fluids can be alkanes, such as octane or decane. Useful fluids can be nitroalkanes, such as nitromethane. Useful fluids can be aromatic compounds, such as toluene or diethylbenzene. Useful fluids can be ketones, such as butanone or methyl isobutyl ketone. Useful fluids can be chlorocarbons, such as chlorobenzene. Useful fluids can be chlorofluorocarbons, such as dichlorofluoroethane or chlorotrifluoroethylene. Other fluids considered for these display assemblies include butyl acetate and dimethylformamide. Still other useful fluids for these displays include hydro fluoro ethers, perfluoropolyethers, hydro fluoro poly ethers, pentanol, and butanol. Example suitable hydro fluoro ethers include ethyl nonafluorobutyl ether and 2-trifluoromethyl-3-ethoxydodecafluorohexane.

A sheet metal or molded plastic assembly bracket 532 holds the cover plate 522, the substrate 504, the backlight and the other component parts together around the edges. The assembly bracket 532 is fastened with screws or indent tabs to add rigidity to the combined display apparatus 500. In some implementations, the light source 518 is molded in place by an epoxy potting compound. Reflectors 536 help return light escaping from the edges of the light guide 516 back into the light guide 516. Not depicted in FIG. 5 are electrical interconnects which provide control signals as well as power to the shutter assemblies 502 and the lamps 518.

In some other implementations, the roller-based light modulator 220, the light tap 250, or the electrowetting-based light modulation array 270, as depicted in FIGS. 2A-2D, as well as other MEMS-based light modulators, can be substituted for the shutter assemblies 502 within the display apparatus 500.

The display apparatus 500 is referred to as the MEMS-up configuration, wherein the MEMS based light modulators are formed on a front surface of the substrate 504, i.e., the surface that faces toward the viewer. The shutter assemblies 502 are built directly on top of the reflective aperture layer 506. In an alternate implementation, referred to as the MEMS-down configuration, the shutter assemblies are disposed on a substrate separate from the substrate on which the reflective aperture layer is formed. The substrate on which the reflective aperture layer is formed, defining a plurality of apertures, is referred to herein as the aperture plate. In the MEMS-down configuration, the substrate that carries the MEMS-based light modulators takes the place of the cover plate 522 in the display apparatus 500 and is oriented such that the MEMS-based light modulators are positioned on the rear surface of the top substrate, i.e., the surface that faces away from the viewer and toward the light guide 516. The MEMS-based light modulators are thereby positioned directly opposite to and across a gap from the reflective aperture layer 506. The gap can be maintained by a series of spacer posts connecting the aperture plate and the substrate on which the MEMS modulators are formed. In some implementations, the spacers are disposed within or between each pixel in the array. The gap or distance that separates the MEMS light modulators from their corresponding apertures is preferably less than 10 microns, or a distance that is less than the overlap between shutters and apertures, such as overlap 416.

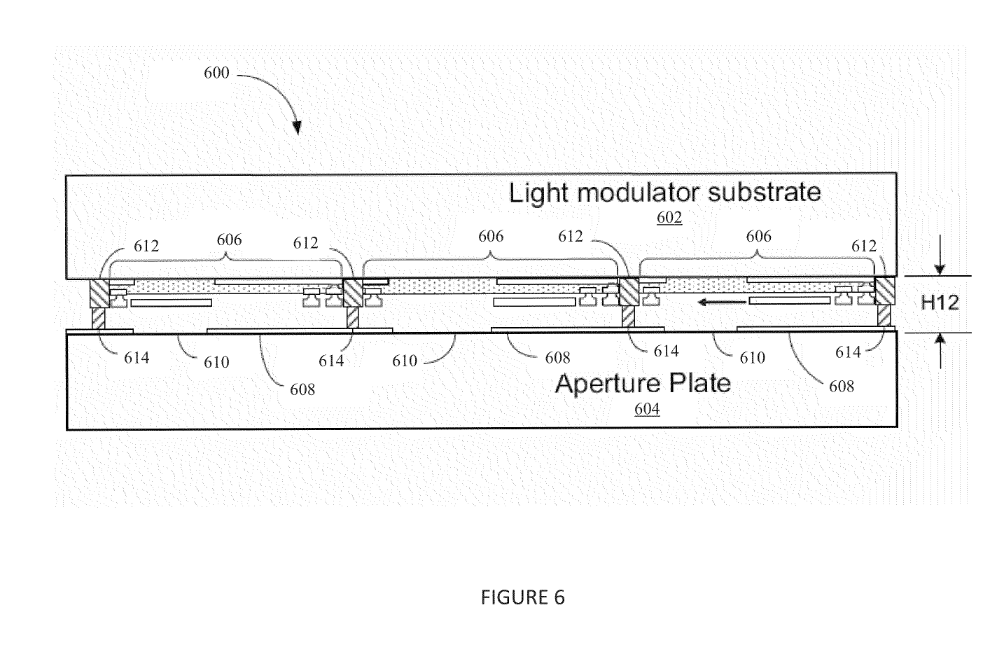

FIG. 6 shows a cross sectional view of a light modulator substrate and an aperture plate for use in a MEMS-down configuration of a display. The display assembly 600 includes a modulator substrate 602 and an aperture plate 604. The display assembly 600 also includes a set of shutter assemblies 606 and a reflective aperture layer 608. The reflective aperture layer 608 includes apertures 610. A predetermined gap or separation between the modulator substrates 602 and the aperture plate 604 is maintained by the opposing set of spacers 612 and 614. The spacers 612 are formed on or as part of the modulator substrate 602. The spacers 614 are formed on or as part of the aperture plate 604. During assembly, the two substrates 602 and 604 are aligned so that spacers 612 on the modulator substrate 602 make contact with their respective spacers 614.

The separation or distance of this illustrative example is 8 microns. To establish this separation, the spacers 612 are 2 microns tall and the spacers 614 are 6 microns tall. Alternately, both spacers 612 and 614 can be 4 microns tall, or the spacers 612 can be 6 microns tall while the spacers 614 are 2 microns tall. In fact, any combination of spacer heights can be employed as long as their total height establishes the desired separation H12.

Providing spacers on both of the substrates 602 and 604, which are then aligned or mated during assembly, has advantages with respect to materials and processing costs. The provision of a very tall, such as larger than 8 micron spacers, can be costly as it can require relatively long times for the cure, exposure, and development of a photo-imageable polymer. The use of mating spacers as in display assembly 600 allows for the use of thinner coatings of the polymer on each of the substrates.

In another implementation, the spacers 612 which are formed on the modulator substrate 602 can be formed from the same materials and patterning blocks that were used to form the shutter assemblies 606. For instance, the anchors employed for shutter assemblies 606 also can perform a function similar to spacer 612. In this implementation, a separate application of a polymer material to form a spacer would not be required and a separate exposure mask for the spacers would not be required.

Typically, spacers can be expensive to fabricate because they typically are fabricated in a separate process from that used to fabricate the rest of the mechanical features of a MEMS display apparatus. This is because the spacers must be both sufficiently narrow because they are located between MEMS light modulators and sufficiently tall so that they provide a sufficient gap between the two substrates. Providing spacers that are sufficiently tall involve a cumbersome fabrication process that includes long times for the cure, exposure, and development of the photo-imageable sacrificial polymer material. Improvements and cost reductions in the process for forming spacers can be realized if spacers are formed using the same materials and with substantially similar processing stages as used to form other portions of the display apparatus, such as the shutter assemblies. As will be described further below, a single fabrication process can be employed to fabricate both the spacers and the MEMS anchor structures. In addition to achieving cost reductions by using only a single fabrication process, employing a single fabrication process can result in the fabrication of anchors that are sufficiently resilient that they also may serve as spacers.

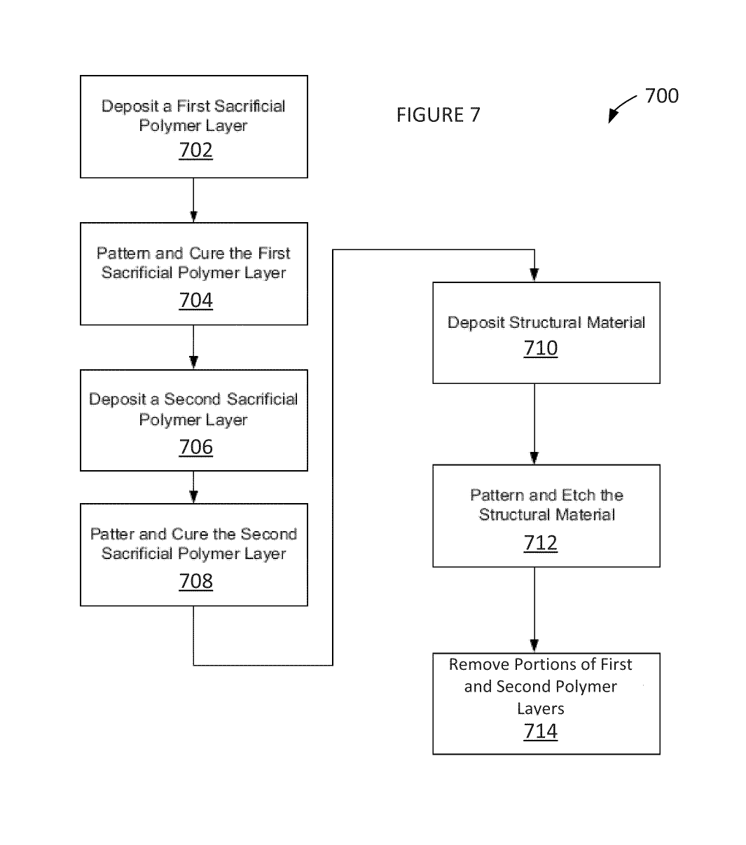

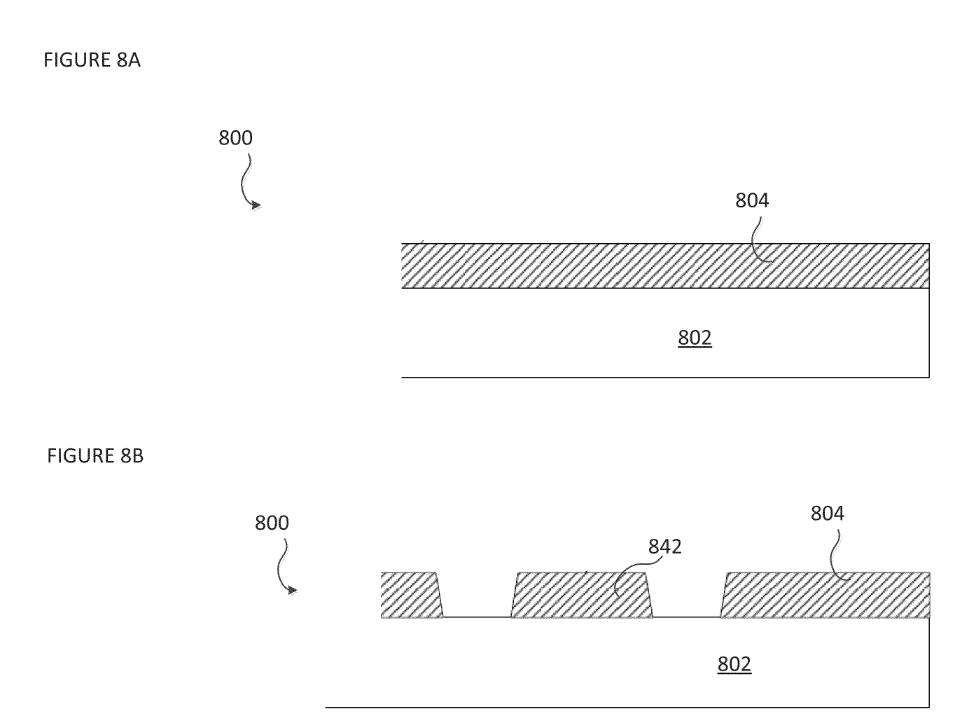

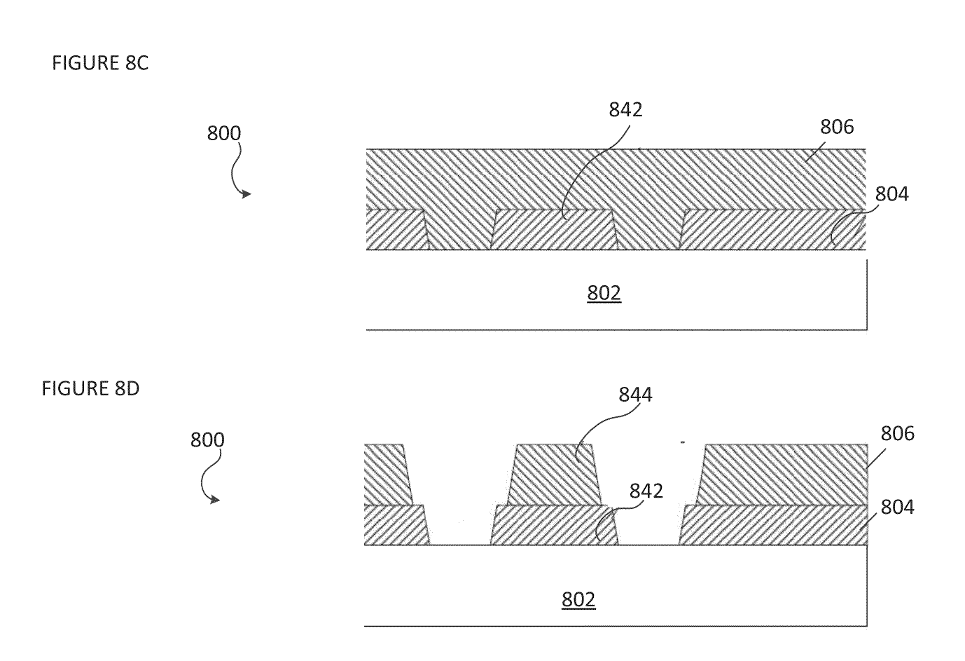

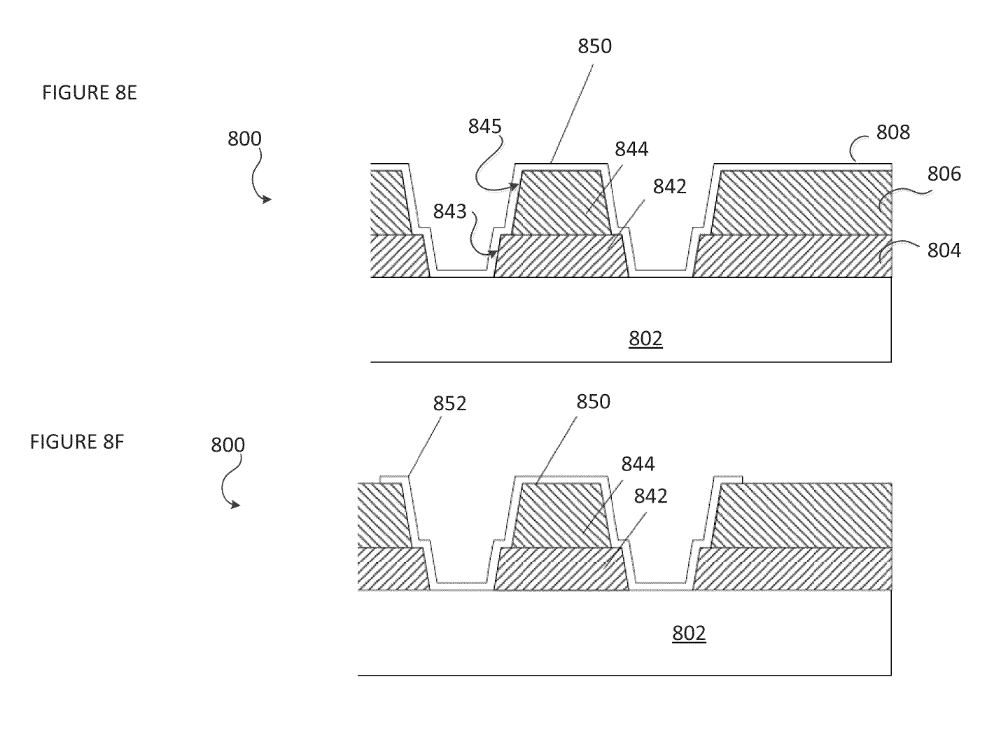

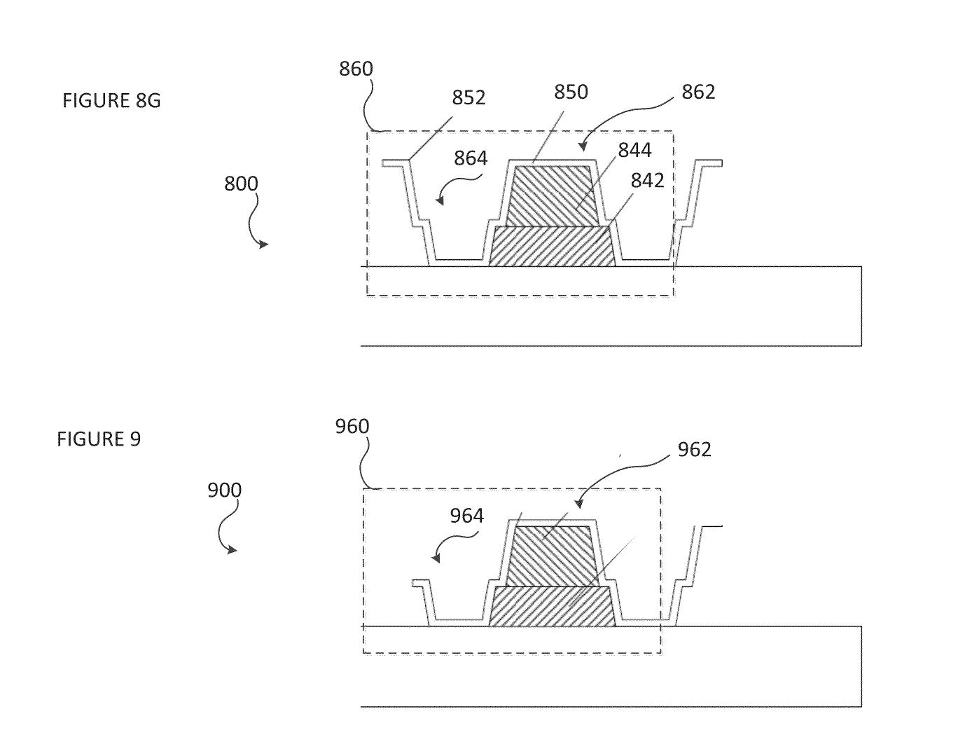

FIG. 7 shows a flow diagram of a fabrication process 700 for simultaneously fabricating spacers and anchors on a substrate for use in a display apparatus. FIGS. 8A-8G show cross-sectional views of stages of construction of an example spacer and anchor assembly 800 using the fabrication process 700 of FIG. 7 described below.

Referring now to FIGS. 7 and 8A-8G, the fabrication process 700 begins with depositing a first sacrificial polymer layer 804 on a first substrate 802 (block 702). The first sacrificial polymer layer 804 is patterned and cured (block 704). A second sacrificial polymer layer 806 is deposited on the first sacrificial polymer layer 804 (block 706). The second sacrificial polymer layer 806 is patterned and cured (block 708). A layer of structural material 808 is deposited on the first and second sacrificial polymer layers 804 and 806 (block 710). The layer of structural material 808 is then patterned and etched (block 712). Portions of the remaining sacrificial polymer layers are then removed (block 714). By way of this fabrication process 700, an integrated anchor-spacer structure, which includes portions of the first and second sacrificial polymer layers 804 and 806 encapsulated by the layer of structural material 808, is formed on the first substrate 802. Each of these stages is described in further detail below.

As set forth above, the fabrication process 700 begins with the deposition of a first sacrificial polymer layer 804 on a first substrate 802 (block 702). For displays built with a MEMS-up configuration, the first substrate 802 can be an aperture layer, such as the light modulator substrate 504 depicted in FIG. 5. For displays built with a MEMS-down configuration, the first substrate 802 can be the light modulator substrate 602 depicted in FIG. 6. The sacrificial polymer layer 804 can be formed from a photo-imageable polymer resist, such as a photo-imageable epoxy, e.g., a novolac epoxy, or a photo-imageable polyimide material. Other polymer families that can be prepared in photo-imageable resist form that may be used as the first sacrificial layer include polyarylene, parylene, benzocyclobutane, perfluorocyclobutane, silsequioxane, silicone polymers, or any combination thereof. In some implementations, the first polymer layer can include a photo-imageable resist commercially known as Nano SU-8 material available from Microchem Corporation, headquartered in Newton, Mass. In other implementations, the first polymer layer can include the Shin Etsu 9553 photoresist, available from Shin-Etsu Chemical Co. Ltd, headquartered in Tokyo, Japan. Other non-photo imageable resists, such as thermoplastic or thermoset polymers used in imprint or other lithography processes also may be employed.

After depositing the first sacrificial polymer layer 804 on the first substrate 802 (block 702), the deposited first sacrificial layer 804 is patterned and cured (block 704). In some implementations, the deposited first sacrificial layer 804 is formulated to allow for many alternate types of curing, including desiccation curing, UV or ultraviolet curing, thermal curing, or microwave curing. In some implementations, the curing process for this polymer is performed at a temperature of approximately 220 degrees Celsius. As part of the patterning process, the first polymer layer is patterned to form portions of the spacers and the anchors. The result of the patterning and curing stage (block 704) is depicted in FIG. 8B, where a first spacer portion 842 is formed.

After patterning and curing the first sacrificial polymer layer 804 (block 704) of the assembly 800, a second sacrificial polymer layer 806 is deposited (block 706) on the assembly 800, the resulting assembly 800 is depicted in FIG. 8C. The second sacrificial polymer layer 806 can be deposited such that it encapsulates exposed surfaces of the assembly 800. The second sacrificial polymer layer 806 is formed from one or more of the polymer materials provided above that can be used to form the first sacrificial polymer layer 804. In some implementations, the second polymer layer 806 may be formed from the same polymer material used to form the first sacrificial polymer layer 804.

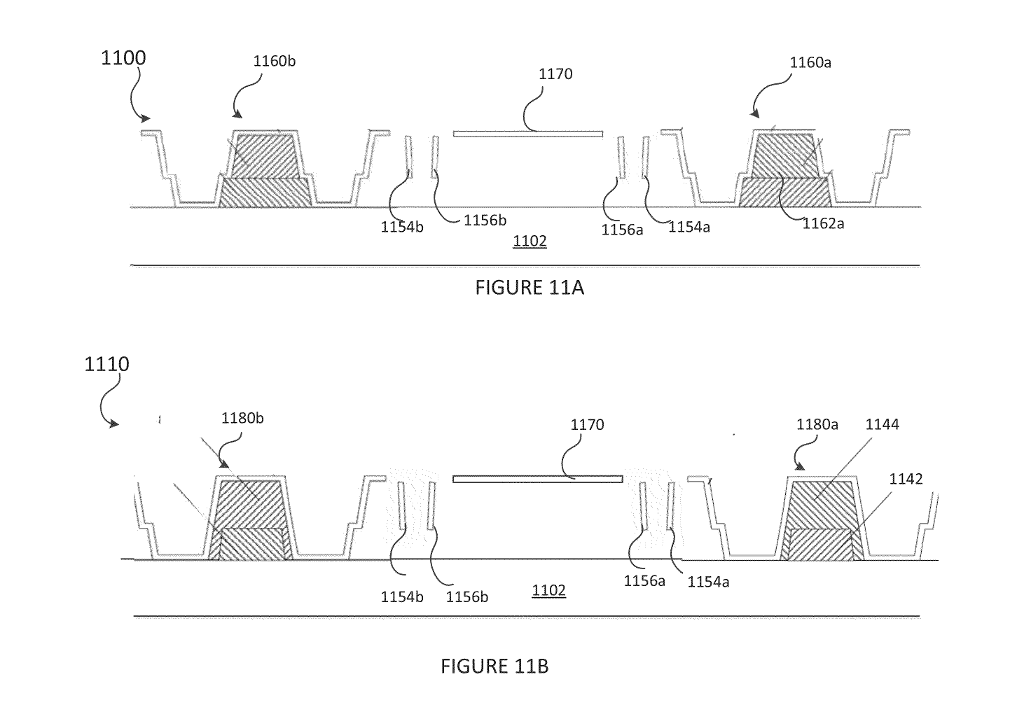

The deposited second sacrificial polymer layer 806 is then patterned and cured (block 708). In particular, the second sacrificial polymer layer 806 is patterned to form a second spacer portion 844. In some implementations of the second sacrificial polymer layer patterning process, the second spacer portion 844 is patterned such that it does not encapsulate the first spacer portion 842 (as depicted in FIG. 8D). In this way, the first spacer portion 842 includes at least one surface 843 that is exposed. In some other implementations of the patterning process, the second polymer layer 806 is patterned such that the second polymer layer 806 encapsulates the first polymer layer 804, as depicted with respect to FIG. 11, which will be described in further detail below. The second sacrificial polymer layer 806 may be cured using a curing technique similar to the curing technique employed for curing the first sacrificial polymer layer 804.

Upon patterning and curing the second sacrificial polymer layer (block 708), a layer of structural material 808 is deposited over the first and second sacrificial layers 804 and 806 (block 710). FIG. 8E shows the result of this process. The layer of structural material 808 can include a single layer of one material, or multiple layers of several different materials. In some implementations, the layer of structural material 808 is deposited such that the layer of structural material 808 contacts and encapsulates the exposed surface 843 of the first spacer portion 842 and an exposed surface 845 of the second spacer polymer portion 844. Depending on the specific materials used to form the layer of structural material, the layer(s) of material that form the layer of structural material 808 can be deposited using a variety of deposition techniques including atomic layer deposition (ALD), PECVD, or other chemical vapor deposition techniques. In some implementations, the layer of structural material can include a semiconductor layer and a metallic layer. More particularly, in some implementations, the layer of structural material includes one or more silicon (Si), titanium (Ti), silicon nitride (SiN) and an oxynitride (OxNy).

In some applications, the contrast of the display can be improved by reducing the reflection of ambient light impinging upon the layer of structural material 808. As such, in some implementations, the layer of structural material can be made of a light absorbent material. For example, the layer of structural material can absorb at least about 70% of light impinging on the layer of structural material. Some metal alloys which are effective at absorbing light, i.e., include, without limitation, chromium-molybdenum (MoCr), molybdenum-tungsten (MoW), molybdenum-titanium (MoTi), molybdenum-tantalum (MoTa), titanium-tungsten (TiW), and titanium-chromium (TiCr). Metal films formed from the above alloys or simple metals, such as nickel (Ni) and chromium (Cr) with rough surfaces also can be effective at absorbing light. Such films can be produced by sputter deposition in high gas pressures (sputtering atmospheres in excess of 20 millitorr). Rough metal films also can be formed by the liquid spray or plasma spray application of a dispersion of metal particles, following by a thermal sintering block. A dielectric layer is then added to prevent spalling or flaking of the metal particles. Semiconductor materials, such as amorphous or polycrystalline silicon (Si), germanium (Ge), cadmium telluride (CdTe), indium gallium Arsenide (InGaAs), colloidal graphite (carbon) and alloys such as silicon-germanium (SiGe) are also effective at absorbing light. These materials can be deposited in films having thicknesses in excess of 500 nm to prevent any transmission of light through the thin film. Metal oxides or nitrides also can be effective at absorbing light, including without limitation copper oxide (CuO), nickel oxide (NiO), chromium (III) oxide (Cr₂O₃), silver oxide (AgO), tin oxide (SnO), zinc oxide (ZnO), titanium oxide (TiO), tantalum pentoxide (Ta₂O₅), molybdenum trioxide (MoO₃), chromium nitride (CrN), titanium nitride (TiN), or tantalum nitride (TaN). The absorption of these oxides or nitrides improves if the oxides are prepared or deposited in non-stoichiometric fashion—often by sputtering or evaporation—especially if the deposition process results in a deficit of oxygen in the lattice. As with semiconductors, the metal oxides should be deposited to thicknesses in excess of, e.g., 500 nm to prevent transmission of light through the film. In addition, a class of materials, called cermets, is also effective at absorbing light. Cermets are typically composites of small metal particles suspended in an oxide or nitride matrix. Examples include Cr particles in a structural material including Cr₂O₃ or Cr particles in a structural material including SiO₂. Other metal particles suspended in the layer of structural material can be nickel (Ni), titanium (Ti), gold (Au), silver (Ag), molybdenum (Mo), niobium (Nb), and carbon (C). Other matrix materials include tin dioxide (TiO₂), tantalum pentoxide (Ta₂O₅), aluminum oxide (Al₂O₃), and silicon nitride (Si₃N₄).

After its deposition, the layer of structural material 808 is patterned and etched (block 712) forming the assembly 800 depicted in FIG. 8F.

Portions of the first and second sacrificial polymer layers 804 and 806 are then removed (block 714) in a release stage, forming an integrated spacer and anchor structure 860 depicted in FIG. 8G. In various implementations, the first and second sacrificial polymer layers 804 and 806 are removed by exposing the spacer and anchor assembly 800 to an oxygen plasma, or in some cases, by thermal pyrolysis. In some implementations, the polymer layers may be removed with either an aqueous or solvent-based stripper compound or plasma ashing. The integrated spacer and anchor structure 860 (the “spacer-anchor 860”) is a single structure that serves both as a spacer as well as an anchor for supporting, over the substrate 802, one or more drive beams 1154a or 1154b or a shutter 1170 via a load beam 1156a or 1156b, as depicted in FIG. 11, which is described below. More particularly, the spacer-anchor 860 includes a spacer portion 862 formed from portions of the first and second polymer layers 842 and 844 encapsulated by the layer of structural material 850. The polymer material 842 and 844 encapsulated within the layer of structural material 808 provides greater structural support to the remainder of the spacer-anchor 860, helping prevent it from bending during operation of the display or as the result of physical or environmental stresses. In various implementations, polymer material may be encapsulated under one or more sides of the anchor, depending on the spacer-anchor position and the direction at which the beam or beams attached to the spacer-anchor 862 extend away from it. For example, in some implementations, a drive beam anchor is formed as a rectangular spacer-anchor 860 that encapsulates polymer along three sides (e.g., each of the sides other than the side from which drive beams extend). In some other implementations, a load beam anchor is formed as a rectangular spacer-anchor 860 that encapsulates polymer along two sides (e.g., a side facing a drive beam anchor and a side facing away from a shutter).

FIG. 9 shows an example cross-sectional view of an alternate configuration of an anchor and shutter assembly 900. The anchor and shutter assembly 900 includes an integrated spacer and anchor structure 960, which includes a spacer portion 962 that is similar to the spacer portion 862 depicted in FIG. 8G, and a lower anchor structure 964. The anchor structure 864 can support a corresponding MEMS structure (not shown) that can be fabricated together with the anchor and shutter assembly 900. The integrated spacer and anchor structure 960 omits the upper portion of one anchor wall included in the integrated spacer and anchor structure 860. This wall faces the risk of being broken if spacers extending from an opposing substrate are misaligned sufficiently that they come into contact with the anchor wall, as opposed to the spacer portion 862, as intended. The wall, if broken, could interfere with the other components of the assembly 800. By eliminating this wall, as depicted in FIG. 9, this risk is mitigated.

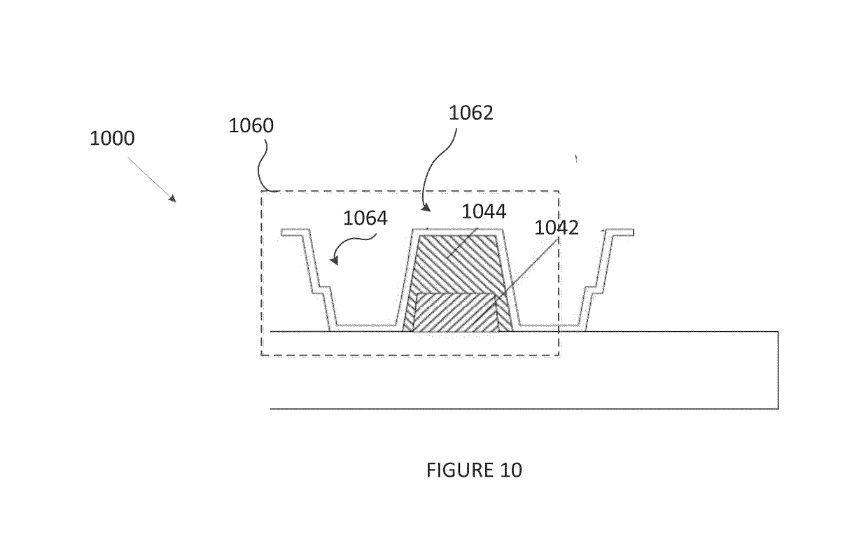

FIG. 10 shows an example cross-sectional view of another alternate configuration of an anchor and shutter assembly 1000. The anchor and shutter assembly 1000 includes an integrated spacer and anchor structure 1060 (the “spacer-anchor 1060”) that includes an anchor portion 1064 having a spacer portion 1062. The spacer portion 1062 is different from the spacer portion 862 depicted in FIG. 8G, in that the spacer portion 1062 includes a second spacer portion 1044 formed from the second polymer layer 806 that encapsulates a first spacer portion 1042 formed from the first polymer layer 804. In other words, the second spacer portion 1044 is in contact with every surface of the first spacer portion not in contact with the first substrate 1002. In turn, the layer of structural material 1050 contacts the second spacer portion 1044 but does not contact any surface of the first spacer portion 1042. Specifically, to fabricate such a configuration, the second sacrificial polymer layer 1006 that is deposited on the first spacer portion 1042 is patterned in such a manner that does not expose the surface 1043 of the first spacer portion 1042.

FIG. 11A shows an example cross-sectional view of an anchor and shutter assembly 1100. The anchor and spacer assembly 1100 includes a first integrated spacer and anchor structure 1160a and a second integrated spacer and anchor structure 1160b, (“spacer-anchors 1160a and 1160b”) that are configured to support a shutter assembly. In this configuration, the spacer-anchors 1160a and 1160b are similar to the spacer-anchor 860 depicted in FIG. 8G. The shutter assembly includes a shutter 1170, a first drive beam 1154a and a first load beam 1156a, and a second drive beam 1154a and a second load beam 1156b. Similar to the drive and load beams described with respect to FIG. 2A, the drive and load beams 1154a, 1154b, 1156a and 1156b are configured to move the shutter 1170 between an open and closed position.

FIG. 11B shows an example cross-sectional view of an anchor and shutter assembly 1110. The anchor and shutter assembly 1110 is similar to the anchor and spacer assembly 1100 depicted in FIG. 11A in that the anchor and spacer assembly 1110 includes similar drive and load beams 1154a and 1154b, and 1156a and 1156b, respectively. However, the anchor and shutter assembly 1110 differs from the anchor and shutter assembly 1100 in that the anchor and shutter assembly 1110 includes a first integrated spacer and anchor assembly 1180a and a second integrated spacer and anchor assembly 1180b (“spacer-anchors 1180a and 1180b”) that are configured to support a shutter assembly including the shutter 1170. In this configuration, the spacer-anchors 1160a and 1160b are similar to the spacer-anchors 1160 depicted in FIG. 11.

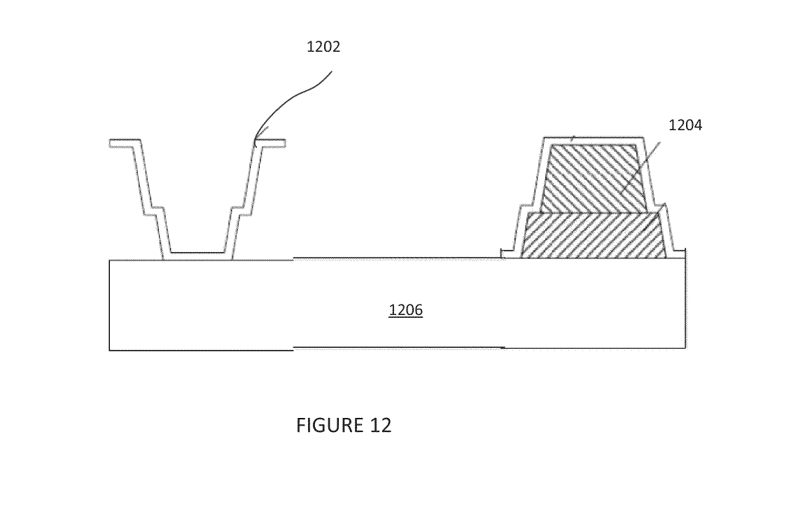

FIG. 12 shows an example cross sectional view of an anchor 1202 and a separate spacer 1204 formed on a substrate 1206 by a single fabrication process. In contrast to the integrated spacer and anchor structures 1162 and 1182 described with respect to FIGS. 11A and 11B, the anchor 1202 and the spacer 1204 are not connected. A person having ordinary skill in the art may readily appreciate that although the spacer 1204 is similar to the spacer portion 1162 depicted in FIG. 11A, the spacer 1204 also can be similar to the spacer portion 1182 depicted in FIG. 11B. In some implementations where the spacers are to be positioned away from the anchors, the configuration depicted in FIG. 12 may be suitable for use.

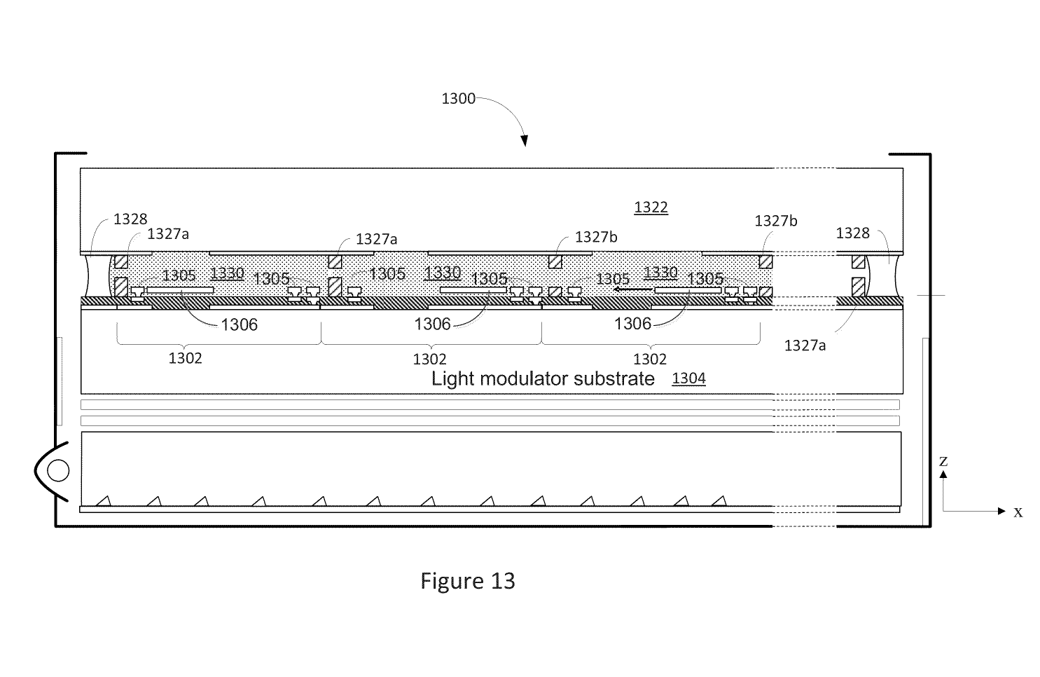

FIG. 13 is a cross sectional view of a display apparatus 1300. The display apparatus 1300 is similar to the display apparatus 500 depicted in FIG. 5. The display apparatus includes an array of shutter assemblies 1302 formed on a light modulator substrate 1304. The light modulator substrate 1304 is separated from a cover plate 1322 by an edge seal 1328 that surrounds the perimeter of the light modulator substrate 1304 and by pairs of spacers 1327a and 1327b (collectively spacers 1327). The space between the light modulator substrate 1304 and the cover plate 1322 is filled with a liquid 1330.

The display apparatus 1300 includes a different spacer architecture than that used in the display apparatus 500 depicted in FIG. 5. The display apparatus 500 includes spacers 527 formed from unitary structures that extend across the entire gap from the light modulator substrate 504 to the cover plate 522. The display apparatus 1300 depicted in FIG. 13 includes spacer pairs 1327a and 1327b. Each of the spacer pairs 1327a and 1327b includes a lower-spacer component extending up from the light modulator substrate 1304 and an upper-spacer component extending down from the cover plate 1322. The heights of the upper and lower components of the spacer pairs 1327a and 1327b are selected such that under at least some operating conditions, opposing spacer components do not contact one another. Instead they are separated by a gap. This gap allows the cover plate 1322 to deform towards the light modulator substrate 1304 as the volume of the liquid 1330 decreases in response to decreases in ambient temperature. The ability for the cover plate 1322 to deform reduces the likelihood of bubble formation.

The spacer pairs 1327a and 1327b differ from one another with respect to the heights of their corresponding lower-spacer components. More particularly, the lower-spacer components of the spacer pairs 1327a are taller than the lower-spacer components of the spacer pairs 1327b. For example, the lower-spacer component of the spacer pairs 1327b are about as tall as the anchors 1305 incorporated into the shutter assemblies 1302 used to support light modulating shutters 1306. For example, these lower-spacer components may be from about 3 to about 5 microns tall. In contrast, the lower-spacer components of the spacer pairs 1327a may be from about 4 to about 7 microns tall. By incorporating spacers 1327 with lower-spacer components having different heights, the degree and location of deformation of the cover plate 1322 caused by ambient temperature fluctuation can be controlled to mitigate optical artifacts that might result from a less controlled deformation.

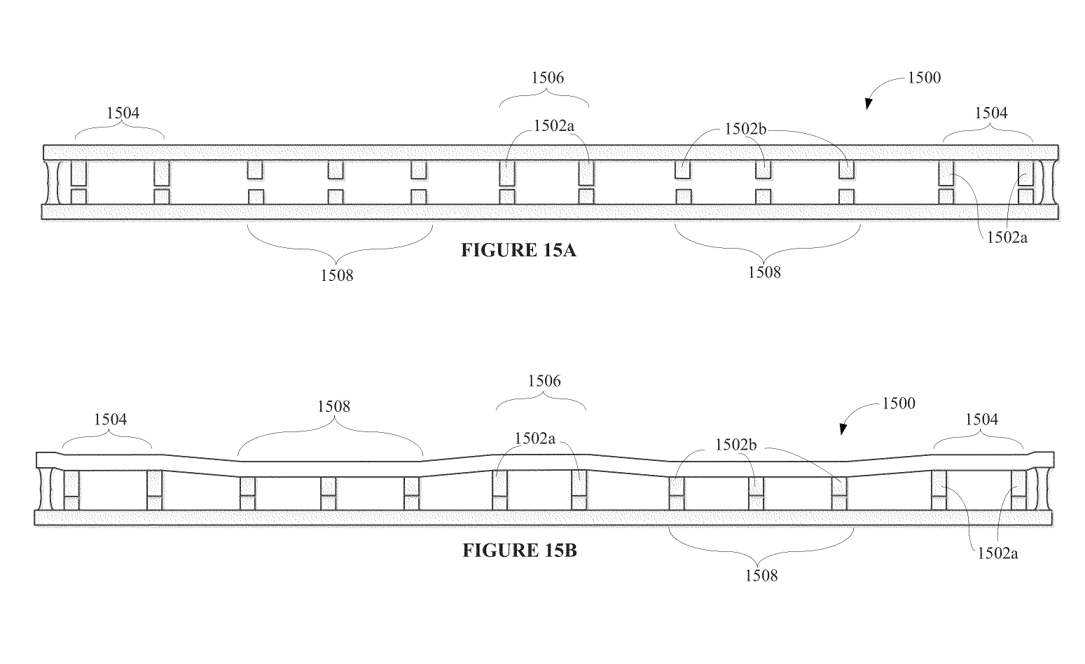

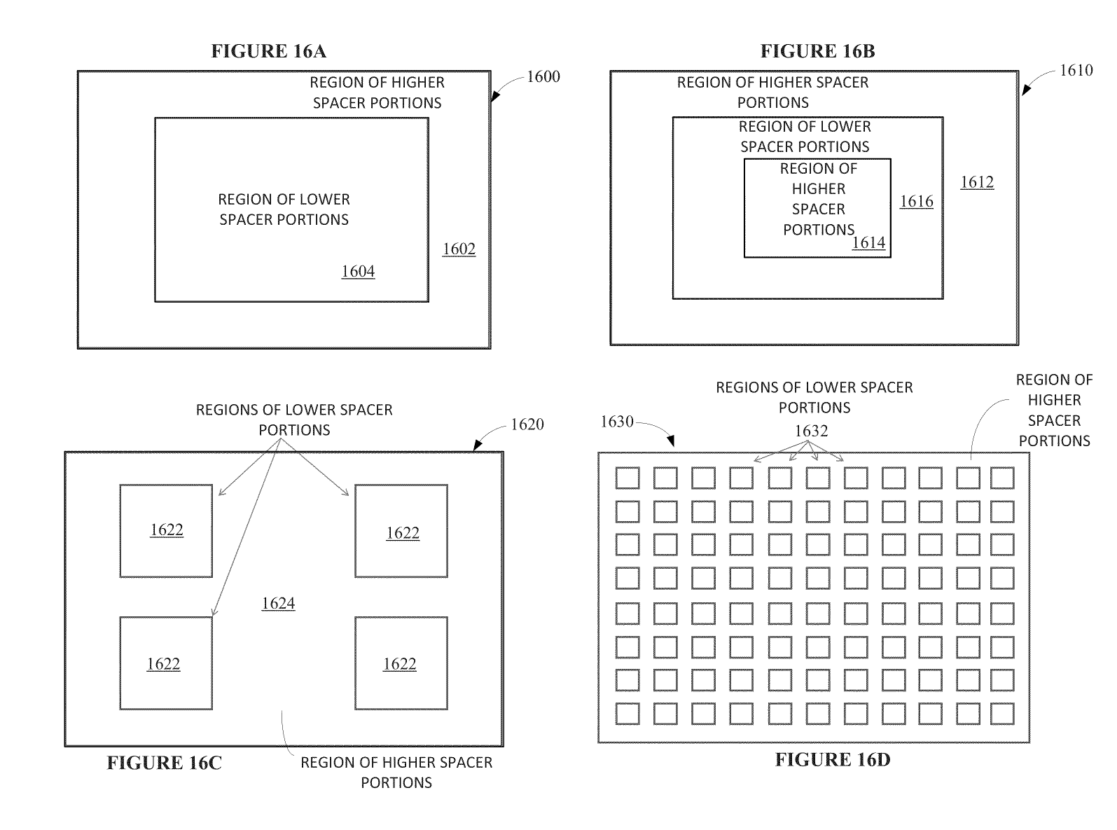

In the display apparatus 1300, the spacer pairs 1327a having taller lower-spacer components are positioned towards the perimeter of the display, near the edge seal 1328. Spacer pairs 1327b having shorter lower-spacer components are located towards the interior of the display. This arrangement provides for a gradual deformation of the cover plate 1322 from the edge of the display towards the interior. Alternative arrangements of spacer pairs having different heights are depicted in FIG. 15B and in FIGS. 16B-16D.

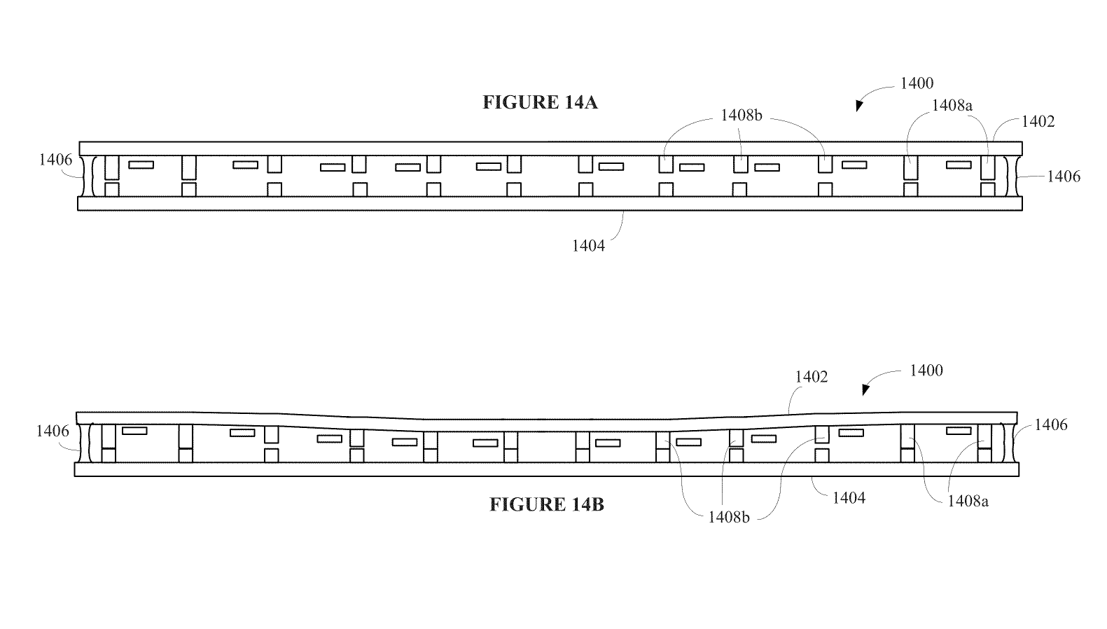

FIGS. 14A and 14B show cross sections of a display apparatus 1400 at two ambient temperatures. FIG. 14A shows the display apparatus 1400 at a temperature of about room temperature, e.g., at about 20° C. FIG. 14B shows the display apparatus 1400 at a temperature substantially below room temperature, such as at or below about 0° C. and possibly as low or lower than −30° C.

As depicted in FIGS. 14A and 14B, the display apparatus 1400 includes a front substrate 1402 and a rear substrate 1404. The front and rear substrates 1402 and 1404 are separated from one another by an edge seal 1406 and two sets of spacers pairs 1408a and 1408b. Each spacer pair 1408a and 1408b includes an upper-spacer component and a lower-spacer component. As with the spacer pairs 1327a and 1327b of the display apparatus 1300 depicted in FIG. 13, the spacer pairs 1408a and 1408b depicted in FIGS. 14A and 14B differ from one another in that the height of one component of the spacer pairs 1408a is different from the height of a corresponding component of the spacer pairs 1408b. More particularly, the upper-spacer components of the spacer pairs 1408a are taller than the upper-spacer components of the spacer pairs 1408b. In the display apparatus 1400, the upper components of the spacer pairs 1408a and 1408b vary in size instead of the lower-spacer components of the spacer pairs 1327 because the display apparatus depicted in FIG. 14 is constructed in a MEMS-down configuration instead of a MEMS-up configuration.

The spacer pairs 1408a and 1408b in the display apparatus 1400 are arranged in a fashion similar to the spacer pairs 1327 depicted in FIG. 13. That is, the spacer pairs 1408a with taller upper-spacer components are positioned toward the perimeter of the display apparatus 1400, whereas the spacer pairs 1408b with shorter upper-spacer components are positioned toward the interior of the display. As the display apparatus 1400 transitions from a room temperature operating environment (depicted in FIG. 14A) to a colder operating environment (depicted FIG. 14B) the front substrate 1402 deforms towards the rear substrate 1404. As a result, the gap between the front and rear substrates 1402 and 1404 gradually decreases until the upper-spacer components and the lower-spacer components of the spacer pairs 1408a and 1408b meet one another, substantially preventing further substrate deformation.

FIGS. 15A and 15B show cross sections of a display apparatus 1500 at two ambient temperatures. FIG. 15A shows the display apparatus 1500 at a temperature of about room temperature, e.g., at about 20° C. FIG. 15B shows the display apparatus 1500 at a temperature substantially below room temperature, such as at or below about 0° C. and possibly as low or lower than −30° C. In contrast to the display apparatus 1400 depicted in FIGS. 14A and 14B, the display apparatus 1500 includes spacer pairs 1502a and 1502b having a different arrangement than the spacer pairs 1408a and 1408b depicted in FIGS. 14A and 14B. As with the spacer pairs 1408a and 1408b, the upper-spacer components of the spacer pairs 1502a are taller than the lower-spacer components of the spacer pairs 1502b. However, instead of the spacer pairs with taller upper-spacer components only being located towards the perimeter of the display apparatus, as depicted in FIGS. 14A and 14B, the display apparatus 1500 depicted in FIG. 15 includes spacer pairs with taller upper components (i.e., spacer components 1502a) both in a region 1504 towards the perimeter of the display apparatus 1500 as well as in a region 1506 in the interior of the display apparatus. These regions are separated by a region 1508 that includes the spacer pairs 1502b that have shorter upper-spacer components.

FIGS. 16A-16D show example arrangements of spacer pairs having varying component heights. FIG. 16A depicts a display apparatus 1600 having a spacer pair arrangement corresponding to the arrangement of spacer pairs in the display apparatus 1400 depicted in FIGS. 14A and 14B. That is, spacer pairs having taller upper-spacer components are positioned towards the perimeter of the display apparatus 1600 in one region 1602, and spacer pairs having shorter upper-spacer components are positioned towards the interior of the display apparatus 1600 in a different region 1604.

FIG. 16B depicts a display apparatus 1610 having a spacer pair arrangement corresponding to the arrangement of spacer pairs in the display apparatus 1500 depicted in FIGS. 15A and 15B. That is, spacer pairs having taller upper-spacer components are positioned towards the perimeter of the display apparatus 1610 in a first region 1612 and in a second region 1614 towards the center of the display apparatus 1610. The first region 1612 and the second region 1614 are separated by a third region 1616 in which spacer pairs have shorter upper-spacer components.

FIG. 16C depicts a display apparatus 1620 having a third spacer pair arrangement. The display apparatus 1620 includes four regions 1622 of spacer pairs having shorter upper-spacer components surrounded by a substantially continuous region 1624 of spacer pairs having taller upper-spacer components.

FIG. 16D depicts a display apparatus 1630 having a fourth spacer pair arrangement. The display apparatus 1630 includes a relatively large number of regions 1632 of spacer pairs having shorter upper-spacer components surrounded by a continuous region 1634 of spacer pairs having taller upper-spacer components. In display apparatus having a relatively small number, such as four, of regions 1632, it may be possible for a viewer to perceive minor changes in viewing angles at the transitions between the regions 1632 and 1634. These transitions would be few and far between, and thus be more noticeable. With a larger number of regions 1632 as shown in FIG. 16D, such as 20 or more regions, transitions between regions 1632 and 1634 would exist relatively frequently across the display. Thus, any particular transition would be less likely to stand out to a viewer.

While only two lower-spacer component heights are depicted in each of the display apparatus depicted in FIGS. 13, 14, 15 and 16A-16D, in some other implementations, a display apparatus can include additional spacer pairs that have components of other heights. For example, in some implementations, the display apparatus includes spacer components having three, four, five or more different heights.

As set forth above, fluids can be used to immerse moving components of MEMS devices, such as MEMS light modulators. Inclusion of a fluid surrounding the mechanical light modulators may introduce some drawbacks, however. In particular, sudden impacts on the display surface can result in fluid flows or pressure waves being propagated through the fluid across the display. These flows or waves can damage the light modulators.

To protect against this risk, fluid barriers can be integrated into the display to shield the light modulators against propagating waves or fluid flows. In some implementations, these fluid barriers can serve a secondary purpose by acting as spacers. In fact, the fluid barriers can be fabricated in the same process described above with respect to the formation of spacers described with respect to FIG. 7. Thus, the fluid barriers can be formed from multiple patterned polymer layers encapsulated by a layer of structural material, such as the layer of structural material used to form the anchors, actuators or other structural components of the mechanical light modulator. In some implementations, components of spacers used to form fluid barriers can be formed having a different height than corresponding components of other spacers.

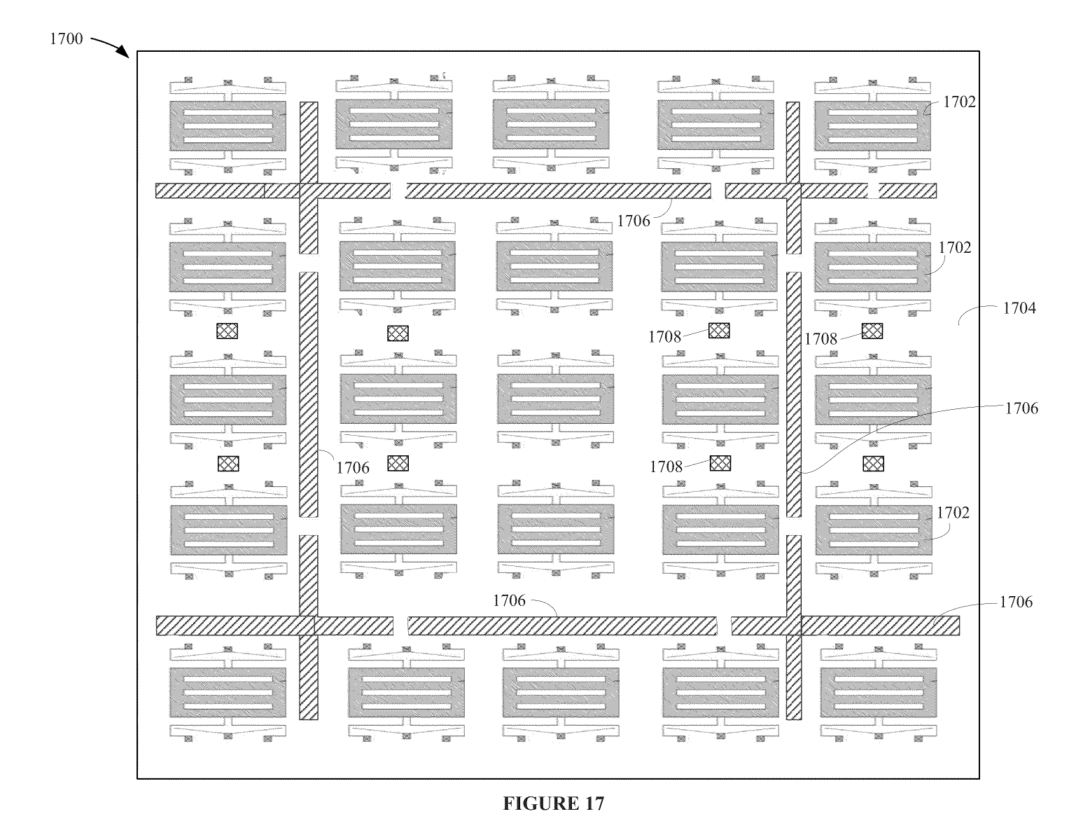

FIG. 17 shows a portion of a display apparatus 1700. The display apparatus 1700 includes an array of MEMS light modulators 1702 formed on a substrate 1704. The fluid barriers 1706 substantially surround several light modulators 1702 and serve as components of spacers that keep an opposing substrate at least a predetermined distance away from the surface of the light modulators 1702. In addition, the display apparatus includes additional interior spacer components 1708 within the interior of each region surrounded by a fluid barrier 1706.

The fluid barriers 1706 are constructed to extend above the light modulators 1702 to impede fluid flow near the surface of the light modulators 1702 that might damage the light modulators 1702. For example, depending on the height of the light modulators and the gap between the substrate 1704 and an opposing substrate, the fluid barriers 1706 may extend about 2-10 microns above the surface of the light modulator most distant from the substrate 1704. Thus, in some implementations including light modulators that extend about 3-5 microns above the substrate, the fluid barriers 1706 may range in height from about 5-7 microns to about 13-15 microns above the substrate 1704, though even taller fluid barriers may be utilized in some other implementations. In contrast, the interior spacer components 1708 are constructed to have about the same height as the light modulators 1702, allowing greater local deformation of the substrate 1704 in colder operating temperatures. Thus, in some implementations, the interior spacer components may extend about 3-5 microns above the substrate 1704 or to whatever height the light modulator extends above the substrate 1704.

In non-light modulator based displays, the fluid barriers extend at least about 1-2 microns above the surface display element incorporated into the display that is most distant from the substrate on which the display element is formed. In some other implementations, the fluid barriers can extend further above the display element surface, e.g., up to 10 microns or more.

In some implementations the opposing substrate includes a plurality of opposing spacer components positioned to contact the fluid barriers 1706 and the interior spacer components 1708. In some implementations, the opposing spacer components all have about the same height.

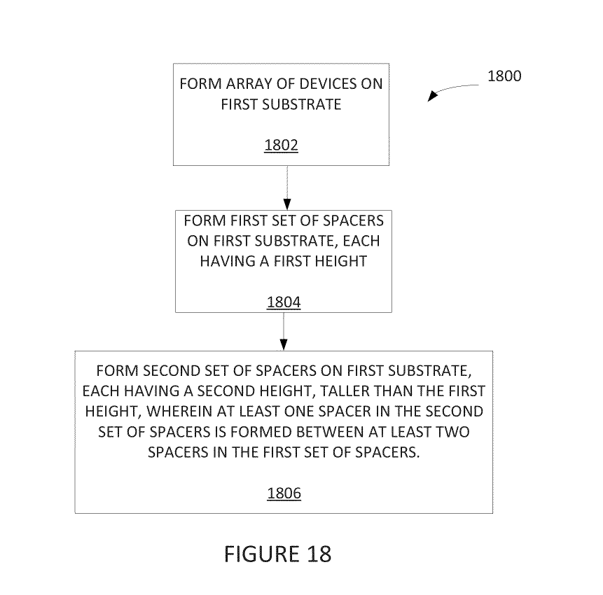

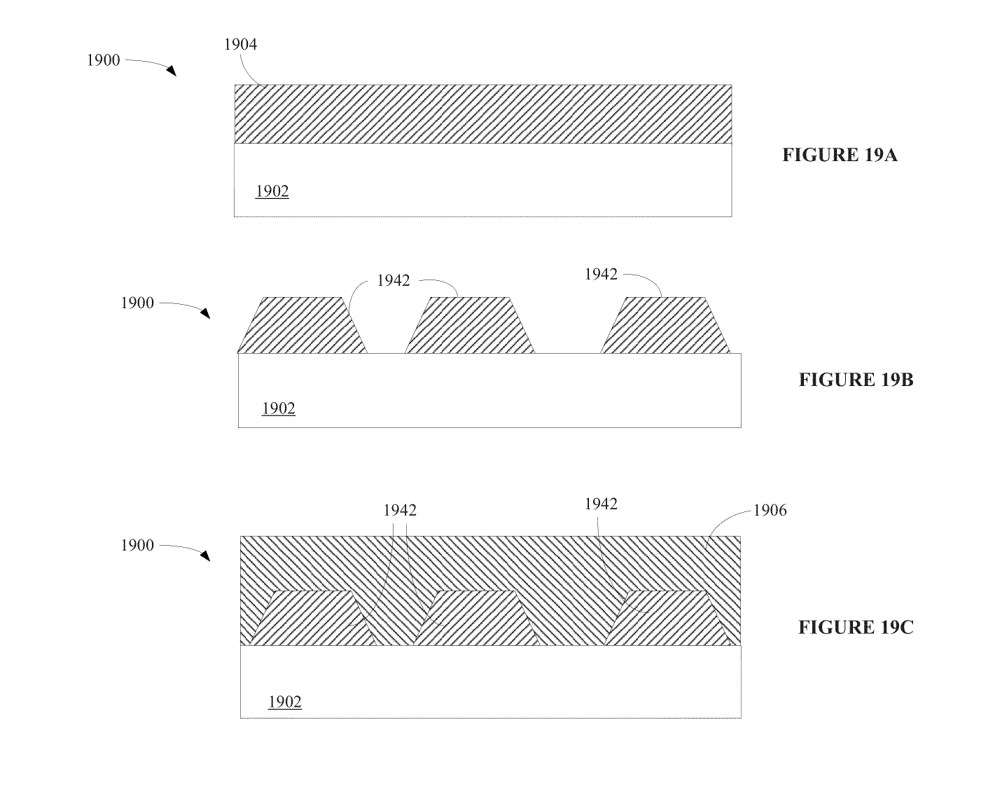

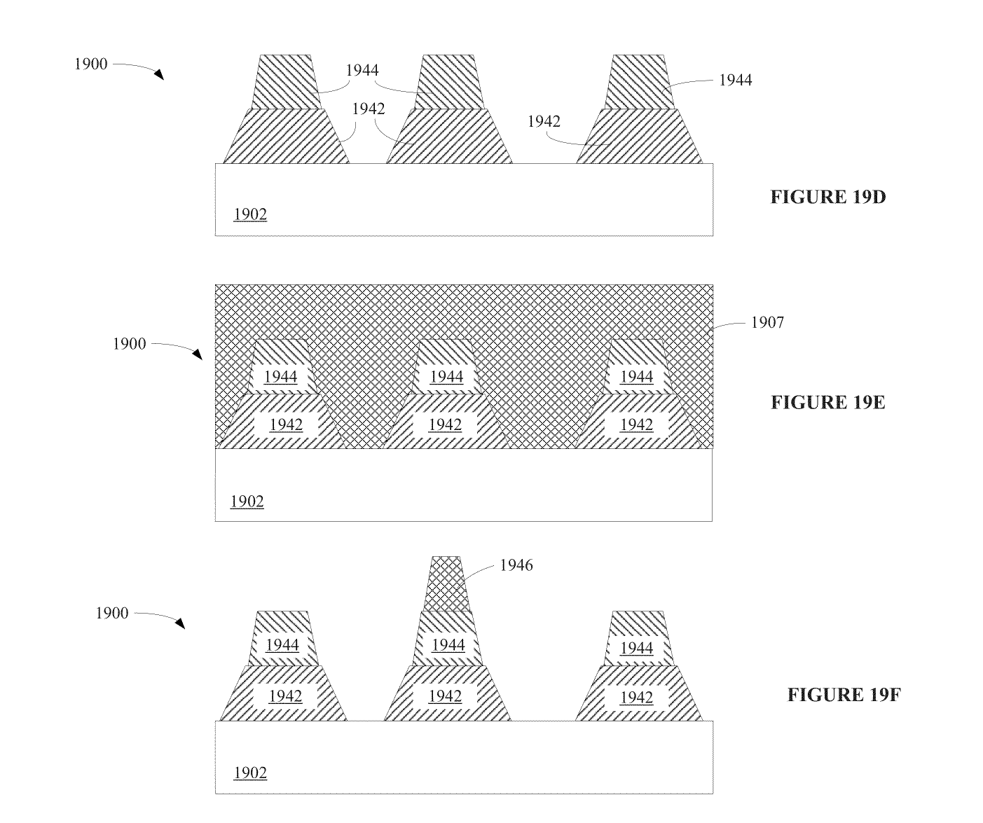

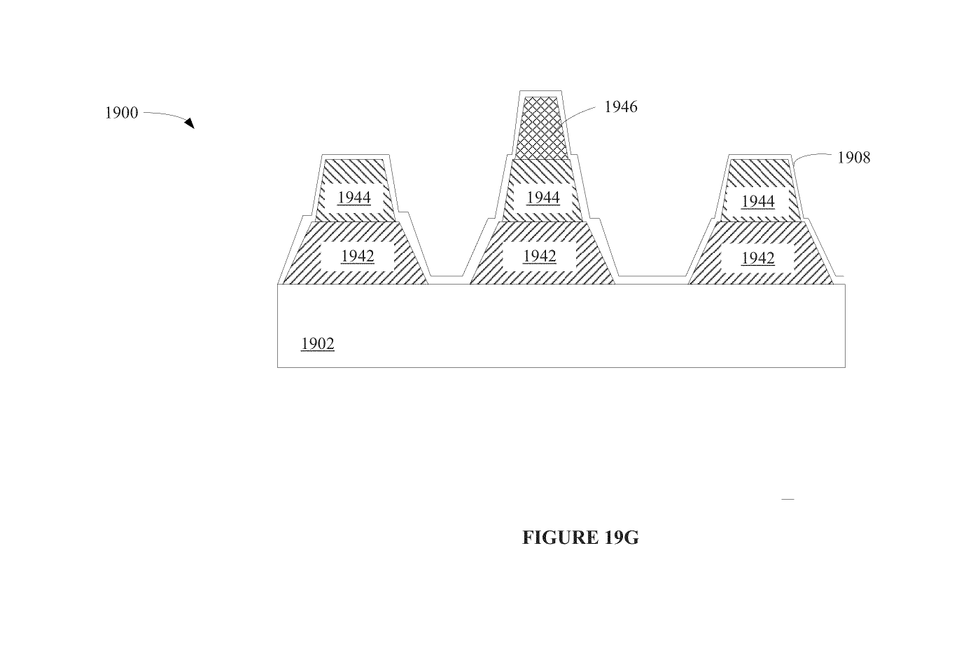

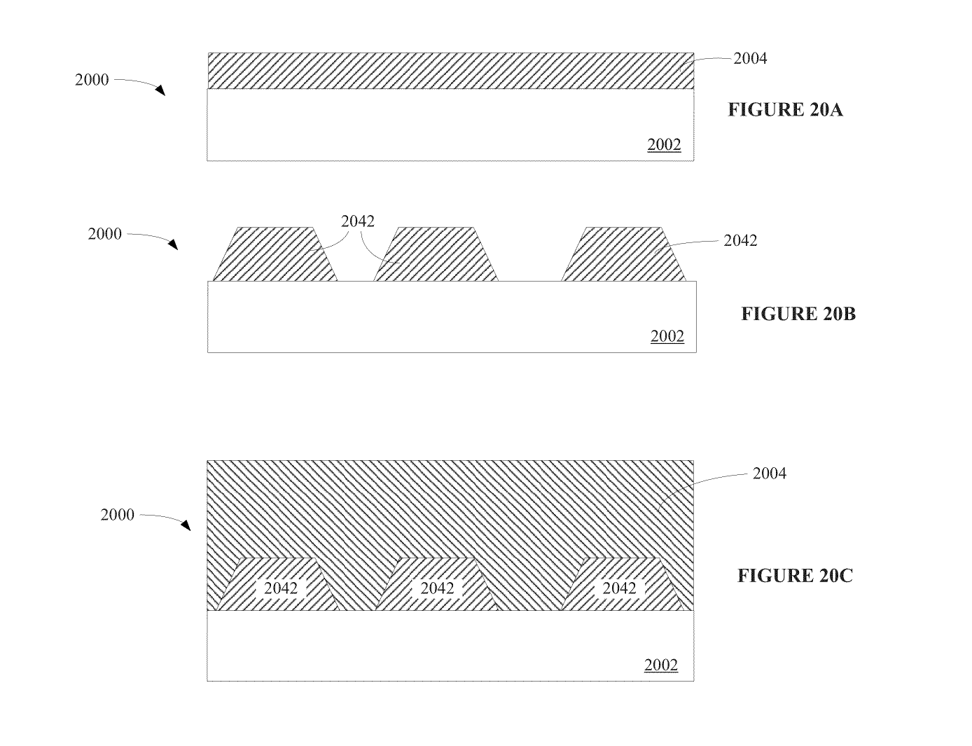

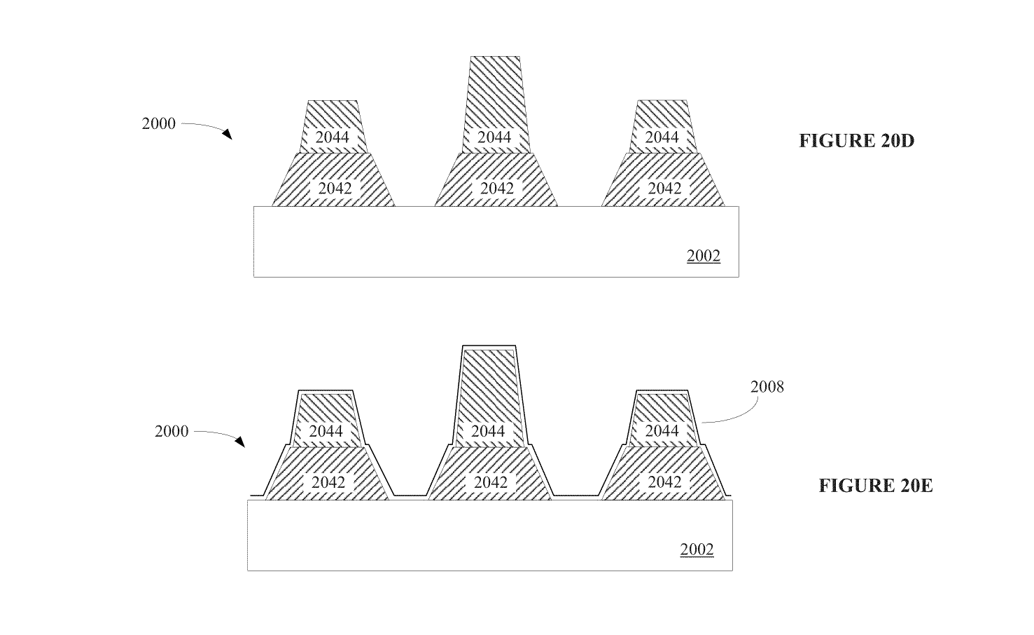

FIG. 18 shows a flow diagram of a method 1800 of forming a plurality of spacers. The method includes forming an array of devices on a first substrate (block 1802) followed by forming first and second sets of spacers on the substrate (blocks 1804 and 1806, respectively). Spacers in the second set of spacers are taller than those in the first set of spacers. Moreover, the sets of spacers are formed such that at lest one spacer in the second set of spacers is formed between at least to spacers in the first set of spacers. Various implementations of the spacer forming stages (blocks 1804 and 1806) are described further below in relation to FIGS. 19A-19G and 20A-20E. In some implementations, such as those described below, the spacer forming stages (blocks 1804 and 1806) are performed simultaneously. In some implementations, the spacer forming stages (blocks 1804 and 1806) can be performed in series.

FIGS. 19A-19G show various stages of a process for manufacturing multi-height spacer components in a display assembly 1900. This process can be used, for example, to implement the method of forming spacers 1800 described above. In general, the process depicted in FIGS. 19A-19G includes the deposition and patterning of three separate polymer layers. The resulting polymer structures are then encapsulated in a structural material to provide rigidity and support. The encapsulated polymer structures form spacer components having varying heights.

The fabrication process begins with the deposition of a first sacrificial polymer layer 1904 on a first substrate 1902. For light modulator-based displays built with a MEMS-up configuration, the first substrate 1902 can be an aperture layer, such as the light modulation substrate 504 depicted in FIG. 5. For light modulator-based displays built with a MEMS-down configuration, the first substrate 1902 can be the light modulator substrate 602 depicted in FIG. 6. The sacrificial polymer layer 1904 can be formed from any of the polymer materials set forth above in relation to FIGS. 7 and 8A-8G.

After depositing the first sacrificial polymer layer 1904 on the first substrate 1902, the deposited first sacrificial polymer layer 1904 is patterned and cured. In some implementations, the deposited first sacrificial polymer layer 1904 is formulated to allow for many alternate types of curing, including desiccation curing, UV or ultraviolet curing, thermal curing, or microwave curing. In some implementations, the curing process for this polymer is performed at a temperature of approximately 220 degrees Celsius. As part of the patterning process, the first sacrificial polymer layer is patterned to form portions of the spacers. The result of the patterning and curing stage is depicted in FIG. 19B, where a first spacer portion 1942 is formed.

After patterning and curing the first sacrificial polymer layer 1904 of the assembly 1900, a second sacrificial polymer layer 1906 is deposited on the assembly 1900. The resulting assembly 1900 is depicted in FIG. 19C. The second sacrificial polymer layer 1906 can be deposited such that it encapsulates exposed surfaces of the assembly 1900. The second sacrificial polymer layer 1906 is formed from one or more of the polymer materials provided above that can be used to form the first sacrificial polymer layer 1904. In some implementations, the second sacrificial polymer layer 1906 may be formed from the same polymer material used to form the first sacrificial polymer layer 1904.

The deposited second sacrificial polymer layer 1906 is then patterned and cured. In particular, the second sacrificial polymer layer 1906 is patterned to form second spacer portions 1944. In some implementations of the second sacrificial polymer layer patterning process, the second spacer portions 1944 are patterned such that they do not encapsulate the first spacer portions 1942 (as depicted in FIG. 19D). In this way, the first spacer portions 1942 include at least one surface that is exposed. In some other implementations of the patterning process, the second polymer layer 1906 is patterned such that the second polymer layer 1906 encapsulates the first polymer layer 1904. The second sacrificial polymer layer 1906 may be cured using a curing technique similar to the curing technique employed for curing the first sacrificial polymer layer 1904.

Upon patterning and curing the second sacrificial polymer layer 1906, a third layer of sacrificial polymer material 1907 is deposited on top of the substrate 1902, the first spacer portions 1942 and the second spacer portions 1944 (as depicted in FIG. 19E). The sacrificial material used to form the third sacrificial polymer layer 1907 can be any of the materials described above as being suitable for the first two layers of the sacrificial material 1904 and 1906.

The third sacrificial polymer layer 1907 is then patterned and cured. For spacer components intended to have lower heights, the third sacrificial polymer layer 1907 on top of the second spacer portions 1944 is completely or substantially removed. For spacer components intended to have taller heights, the third sacrificial polymer layer 1907 is patterned such that third spacer portions 1946 remain on top of the first and second spacer portions 1942 and 1944. FIG. 19F shows the results of this process. In some implementations, the third spacer portions 1946 encapsulates either one or both of the first and second spacer portions 1942 and 1944. In some other implementations, the sides of one or both of the first and second spacer portions 1942 and 1944 remain exposed.

A layer of structural material 1908 is then deposited over the first, second and third sacrificial layers 1904, 1906 and 1907. The layer of structural material 1908 can be formed of any of the materials in any of the configurations described above with respect to the layer of structural material 808 depicted in FIG. 8E. The result of this stage of processing is depicted in FIG. 19G. The assembly 1900 is an example of an assembly in which at least one taller spacer is positioned between at least two shorter spacers. After its deposition, the layer of structural material 1908 is patterned as desired.

FIGS. 20A-20E show various stages of an alternative process for manufacturing multi-height spacer components in a display assembly 2000. This process can be used, for example, as an alternative way of implementing the method of forming spacers 1800 described above in relation to FIG. 18. In general, the process depicted in FIGS. 20A-20E includes the deposition and patterning of two polymer layers. The second polymer is patterned using a half-tone or grayscale mask to obtain spacer portions of different heights. The resulting polymer structures are then encapsulated in a structural material to provide rigidity and support. The encapsulated polymer structures form spacer components having varying heights.

The fabrication process begins with the deposition of a first sacrificial polymer layer 2004 on a first substrate 2002. For light modulator-based displays built with a MEMS-up configuration, the first substrate 2002 can be an aperture layer, such as the light modulation substrate 504 depicted in FIG. 5. For light modulator-based displays built with a MEMS-down configuration, the first substrate 2002 can be the light modulator substrate 602 depicted in FIG. 6. The sacrificial polymer layer 2004 can be formed from a any of the polymer materials set forth above in relation to FIGS. 7 and 8A-8G.

After depositing the first sacrificial polymer layer 2004 on the first substrate 2002, the deposited first sacrificial layer 2004 is patterned and cured. In some implementations, the deposited first sacrificial layer 2004 is formulated to allow for many alternate types of curing, including desiccation curing, UV or ultraviolet curing, thermal curing, or microwave curing. In some implementations, the curing process for this polymer is performed at a temperature of approximately 220 degrees Celsius. As part of the patterning process, the first polymer layer is patterned to form portions of the spacers. The result of the patterning and curing stage is depicted in FIG. 20B, where a first spacer portion 2042 is formed.

After patterning and curing the first sacrificial polymer layer 2004 of the assembly 2000, a second sacrificial polymer layer 2006 is deposited on the assembly 2000. The resulting assembly 2000 is depicted in FIG. 20C. The second sacrificial polymer layer 2006 can be deposited such that it encapsulates exposed surfaces of the assembly 2000. The second sacrificial polymer layer 2006 is formed from one or more of the polymer materials provided above that can be used to form the first sacrificial polymer layer 2004. In some implementations, the second polymer layer 2006 may be formed from the same polymer material used to form the first sacrificial polymer layer 2004.

The deposited second sacrificial polymer layer 2006 is then patterned and cured. In particular, the second sacrificial polymer layer 2006 is patterned to form a second spacer portion 2044. A half-tone or grayscale mask is used to vary the degree of UV exposure to different portions of the second sacrificial polymer layer 2006. This differential exposure results in some second spacer portions 2044 having a first height and other second spacer portions having a second height.

In some implementations of the second sacrificial polymer layer patterning process, the second spacer portion 2044 is patterned such that it does not encapsulate the first spacer portion 2042 (as depicted in FIG. 20D). In this way, the first spacer portion 2042 includes at least one surface that is exposed. In some other implementations of the patterning process, the second polymer layer 2006 is patterned such that the second polymer layer 2006 encapsulates the first polymer layer 2004. The second sacrificial polymer layer 2006 may be cured using a curing technique similar to the curing technique employed for curing the first sacrificial polymer layer 2004.

A layer of structural material 2008 is then deposited over the first and second sacrificial layers 2004 and 2006. The layer of structural material 2008 can be formed of any of the materials in any of the configurations described above with respect to the layer of structural material 808 depicted in FIG. 8E. The result of this stage of processing is depicted in FIG. 20E. The assembly 2000 is an example of an assembly in which at least one taller spacer is positioned between at least two shorter spacers. After its deposition, the layer of structural material 2008 is patterned as desired.

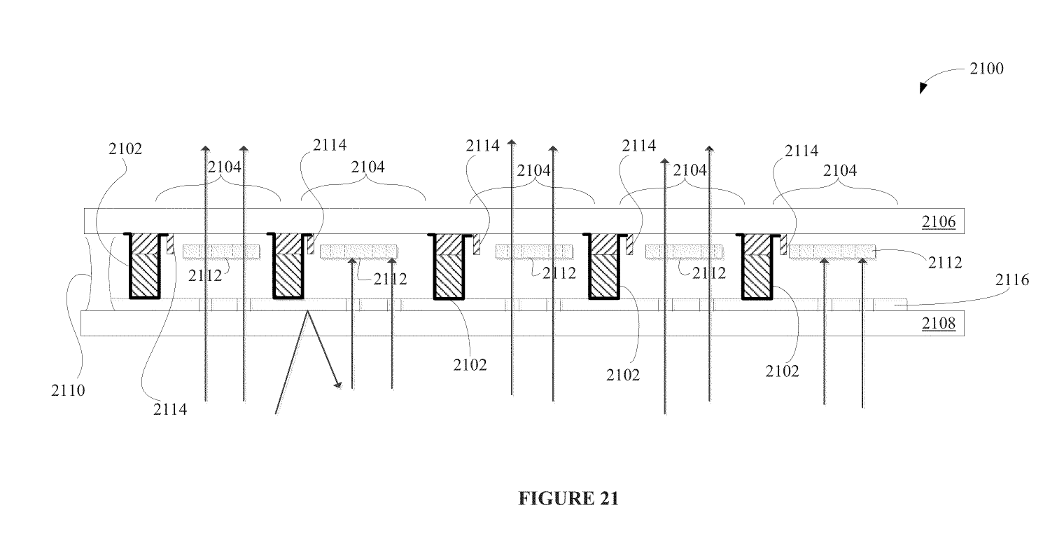

FIG. 21 shows a portion of a display apparatus 2100 having conductive spacers 2102. The display apparatus 2100 includes a plurality of shutter-based light modulators 2104 formed on a first substrate 2106. The first substrate is separated from a second substrate 2108 by an edge seal 2110 and a plurality of conductive spacers 2102. Together, the edge seal 2110 and the conductive spacers 2102 maintain at least a predetermined gap between the first and second substrates 2106 and 2108.

The shutter-based light modulators 2104 include shutters 2112, which are supported over the first substrate 2106 by corresponding anchors 2114. The anchors 2114 both provide mechanical support for the shutters 2112 as well as provide an electrical connection to a control matrix (such as the control matrix 300 depicted in FIGS. 3A and 3B) formed on the first substrate 2106 below the shutter-based light modulators 2104. To provide the electrical connection, the anchors 2114 are either formed of a conductive material or are formed from a non-conductive material coated with a conductive material.

Each conductive spacer 2102 electrically couples to a corresponding anchor, such as the load anchor 208 depicted in FIG. 2, at one end. At a second end, each conductive spacer 2102 electrically couples to a portion of a conductive layer 2116 deposited on the second substrate 2108. Thus, each conductive spacer 2102 electrically connects a shutter 2102 to a corresponding opposing portion of the conductive layer 2116. The electrical connection maintains the shutter 2112 and the corresponding portion of the conductive layer 2116 at a common electrical potential, thereby substantially preventing any electrostatic attraction between the two components. The conductive layer 2116, in some implementations, forms a rear-facing metal reflective layer deposited to enhance light recycling within a backlight positioned behind the second substrate 2108.

In some implementations, the spacers electrically couple to the conductive layer 2116 merely by physical contact. That is, the conductive spacers 2102 are not permanently affixed to the conductive layer 2116, and their connection to the conductive layer 2116 may be temporarily broken if the second substrate deforms, for example due to increases in ambient temperatures. In some of such implementations, the conductive spacers 2102 can be manufactured to have a height substantially equal to the full distance between the first and second substrates 2106 and 2108.

In some other implementations, the conductive spacers 2116 can be manufactured to have a height that is less than the full distance between the first and second substrates 2106. In some of such implementations, the first and second substrates 2106 and 2108 are coupled to one another at their respective edges such that the first substrate 2106 is deformed inward towards the second substrate to have a partially concave shape under a range of common ambient operating temperatures. The concavity of the first substrate 2106 allows most if not all of the conductive spacers to contact, and therefore form an electrical connection with, corresponding portions of the conductive layer 2108.

In still some other implementations, the conductive spacers are 2116 are formed to have a height less than the distance between the first and second substrates 2106 and 2108, and a corresponding set of opposing conductive spacers are formed on the second substrate 2108, such that under a range of common ambient operating temperatures, the conductive spacers 2102 are in contact, and form an electrical connection with, distal ends of the opposing conductive spacers. The proximal ends of the opposing conductive spacers are coupled to portions of the conductive layer 2116.

In some other implementations, the conductive spacers are substantially permanently adhered to the conductive layer during the manufacturing process. They can be adhered, e.g., using a conductive adhesive or solder.

The conductive spacers can be manufactured, without limitation, according to any of the processes depicted and described and above, including, for example, the processes depicted in FIGS. 19A-G and 20A-E. Thus, in some implementations, the conductive spacers are formed from two or more layers of polymer material encapsulated in a conductive structural material. A non-limiting set of suitable conductive structural materials is described above in relation to FIG. 8E.

As depicted in FIG. 21, the anchors 2114 are separate from the conductive spacers 2102. In some other implementations, conductive spacers are integrated into the anchors 2114. In such implementations, the anchors can extend above the height of the shutters 2112 or they may be configured to meet opposing conductive spacers extending from the second substrate 2108. Moreover, while the display apparatus 2100 is depicted having a MEMS-down orientation, similar conductive spacers can be incorporated into display apparatus having a MEMS-up orientation.

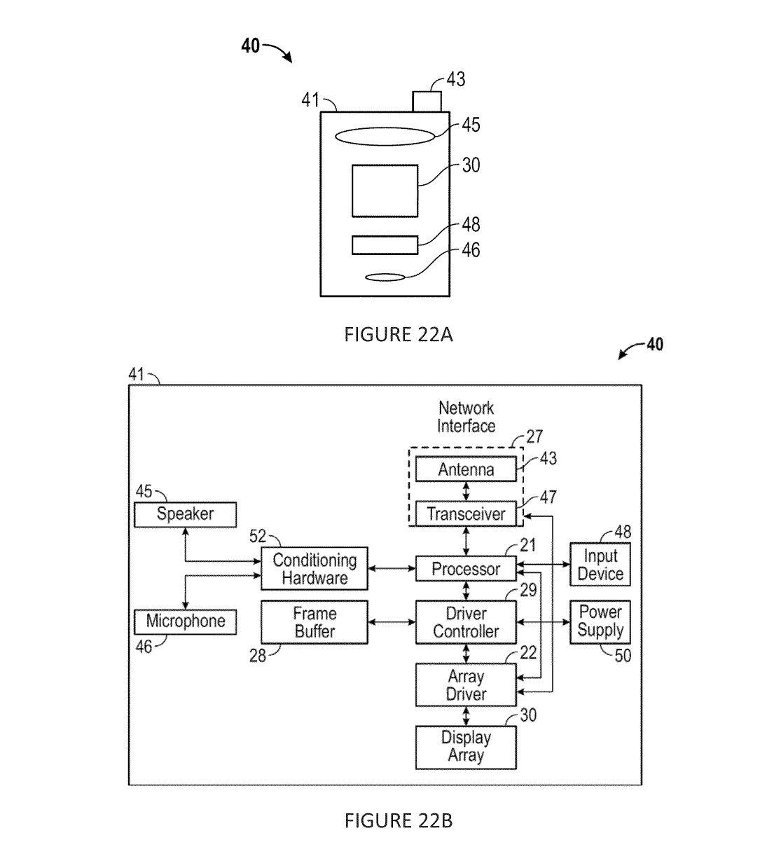

FIGS. 22A and 22B are system block diagrams illustrating a display device 40 that includes a plurality of display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 30 can include a mechanical light modulator-based display, as described herein.

The components of the display device 40 are schematically illustrated in FIG. 16A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 16A, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements. In some implementations, the array driver 22 and the display array 30 are a part of a display module. In some implementations, the driver controller 29, the array driver 22, and the display array 30 are a part of the display module.

In some implementations, the driver controller 29, the array driver 22, and the display array 30 are appropriate for any of the types of displays described herein. For example, the driver controller 29 can be a conventional display controller or a bi-stable display controller (such as a mechanical light modulator display element controller). Additionally, the array driver 22 can be a conventional driver or a bi-stable display driver (such as a mechanical light modulator display element controller). Moreover, the display array 30 can be a conventional display array or a bi-stable display array (such as a display including an array of mechanical light modulator display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising:
an array of devices formed on a first substrate;
a second substrate spaced away from the first substrate such that the array of devices are positioned between the first and second substrates; and
a plurality of spacers coupled to the first substrate to maintain at least a minimum gap between the first substrate and the second substrate, wherein the plurality of spacers include a first set of spacers and a second set of spacers, and the spacers in the first set of spacers are shorter than the spacers in the second set of spacers;
wherein at least one spacer in the second set of spacers is positioned between at least two spacers in the first set of spacers.

2. The apparatus of claim 1, further comprising a liquid filling a gap between the first and second substrates.

3. The apparatus of claim 1, wherein groups of spacers from the first and second sets of spacers are co-located to form a plurality of regions of spacers having lower-spacers and a plurality of regions of spacers having higher spacers.

4. The apparatus of claim 3, comprising:
a first group of spacers including spacers from the second set of spacers positioned about the perimeter of the first substrate;
a second group of spacers including spacers from the first set of spacers positioned within an interior region of the first substrate; and
a third group of spacers including spacers from the second set of spacers positioned within the interior region of the first substrate such that at least one spacer in the second group of spacers is located between at least one spacer in the first group of spacers and at least one spacer in the third group of spacers.

5. The apparatus of claim 3, comprising:
a first group of spacers including spacers from the second set of spacers positioned about the perimeter of the first substrate;
a second group of spacers including spacers from the first set of spacers positioned within an interior region of the first substrate; and
a plurality of third groups of spacers including spacers from the second set of spacers, each of the third groups positioned within the interior region of the first substrate such that at least one spacer in the second group of spacers is located between at least one spacer in the first group of spacers and at least one spacer in each respective third group of spacers.

6. The device of claim 1, wherein the plurality of spacers comprise a metal encapsulating polymer projections extending away from the first substrate.

7. The device of claim 1, wherein the devices in the array comprise display elements, and the apparatus comprises a display incorporating the display elements.

8. The apparatus of claim 7, wherein the display elements comprise light modulators.

9. The apparatus of claim 8, wherein the display elements comprise electromechanical systems (EMS) light modulators.

10. The apparatus of claim 9, wherein the EMS light modulators comprise microelectromechanical systems (MEMS) shutter assemblies.

11. The apparatus of claim 7, further comprising:
a processor that is configured to communicate with the display, the processor being configured to process image data; and
a memory device that is configured to communicate with the processor.

12. The apparatus of claim 11, further comprising:
a driver circuit configured to send at least one signal to the display; and
a controller configured to send at least a portion of the image data to the driver circuit.

13. The apparatus of claim 11, further comprising an image source module configured to send the image data to the processor, wherein the image source module comprises at least one of a receiver, transceiver, and transmitter.

14. The apparatus of claim 11, further comprising an input device configured to receive input data and to communicate the input data to the processor.

15. The apparatus of claim 1, wherein the devices comprise electromechanical systems (EMS) devices.

16. The apparatus of claim 1, wherein the spacers in the first set of spacers are sufficiently tall to prevent the devices from coming into contact with the second substrate.

17. The apparatus of claim 1, wherein the first set of spacers comprise two polymer layers and the second set of spacers comprise three polymer layers.

18. The apparatus of claim 1, wherein:
the first set of spacers comprises a first polymer layer having a first height and a second polymer layer having a second height; and
the second set of spacers comprises a first polymer layer having the first height and a second polymer layer having a third height greater than the second height.

19. The apparatus of claim 1, wherein spacers in at least one of the first set of spacers and the second set of spacers are electrically conductive.

20. The apparatus of claim 19, wherein the electrically conductive spacers electrically connect at least a portion of each of the devices to a conductive element formed on the second substrate.

21. A method of forming a plurality of spacers, comprising:
forming an array of devices on a substrate;
forming a first set of spacers on the substrate, each having a first height; and
forming a second set of spacers on the substrate, each having a second height, taller than the first height, wherein at least one spacer in the second set of spacers is formed between at least two spacers in the first set of spacers.

22. The method of claim 21, wherein forming the first and second sets of spacers comprises patterning a layer of polymer material with a grayscale mask such that a smaller portion of the polymer material remains to form a portion of the first set of spacers than remains for the second set of spacers.

23. The method of claim 21, wherein forming the first and second sets of spacers comprises depositing at least two layers of spacer material on the substrate and patterning the at least two layers of the spacer material such that spacers in the second set of spacers include material from a greater number of layers of spacer material than the spacers in the first set of spacers.

24. The method of claim 21, wherein forming the first and second sets of spacers comprises encapsulating a plurality of polymer protrusions in at least one of a metal and a semiconductor.

25. The method of claim 21, wherein forming the first and second sets of spacers comprises encapsulating a plurality of polymer protrusions in a conductive material.

26. A display apparatus comprising:
an array of image formation means for outputting a plurality of image pixels;
a plurality of first spacing means for maintaining at least a first distance between the image formation means and an opposing substrate; and
a plurality of second spacing means for maintaining at least a second distance, greater than the first distance between, between the image formation means and the opposing substrate, wherein at least one of the first spacing means is positioned between at least two second spacing means.

27. The display apparatus of claim 21, wherein at least one of the first and second spacing means comprise means for maintaining at least a portion of the image formation means at a common potential as a component formed on the opposing substrate.

28. The display apparatus of claim 26, wherein the image formation means comprise means for modulating light output by a backlight.

29. The display apparatus of claim 26, wherein the image formation means comprise means for selectively emitting light.
